(19) United States
(12) Patent Application Publication
(10) Pub. No.: US 2025/0226374 A1
(43) Pub. Date: Jul. 10, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Yongbum Kwon, Suwon-si (KR); Unbyoung Kang, Suwon-si (KR); Kuyoung Kim, Suwon-si (KR)

(21) Appl. No.: 18/969,569

(22) Filed: Dec. 5, 2024

(30) Foreign Application Priority Data
Jan. 4, 2024 (KR) 10-2024-0001388

(51) Int. Cl. H01L 25/18; H01L 21/311; H01L 23/00; H01L 23/367; H01L 23/48; H01L 23/528; H01L 23/532; H10B 80/00

(52) U.S. Cl. CPC H01L 25/18; H01L 21/31144; H01L 23/481; H01L 23/5283; H01L 23/53295; H01L 24/32; H01L 23/3672; H01L 24/05; H01L 24/16; H01L 24/73; H01L 24/96; H01L 24/97; H01L 2224/05018; H01L 2224/05082; H01L 2224/05558; H01L 2224/05573; H01L 2224/16147; H01L 2224/16225; H01L 2224/32145; H01L 2224/32225; H01L 2224/73204; H01L 2224/96; H01L 2224/97; H01L 2225/06513; H01L 2225/06517; H01L 2225/06544; H01L 2924/30101; H10B 80/00

(57) ABSTRACT

A semiconductor package includes a buffer die and a memory die sequentially stacked. The buffer die includes a first substrate having first and second surfaces, a through electrode extending through the first substrate and having a protrusion portion, a protective pattern on the second surface of the first substrate and covering a sidewall of the protrusion portion, a first conductive pad on the protective pattern and contacting the through electrode, and a filling pattern contacting an upper surface of the protective pattern and a sidewall of the first conductive pad and including an inorganic insulating material. The memory die includes a second substrate having first and second surfaces, and a second conductive pad and a conductive connection terminal sequentially stacked beneath the first surface of the second substrate. The first conductive pad contacts the conductive connection terminal.

### CROSS-REFERENCE TO RELATED APPLICATION

This application claims priority under 35 U.S.C. § 119 to Korean Patent Application No. 10-2024-0001388, filed on Jan. 4, 2023 in the Korean Intellectual Property Office (KIPO), the contents of which are herein incorporated by reference in their entirety.

### BACKGROUND

### 1. Field

Example embodiments relate to a semiconductor package and a method of manufacturing the same. More particularly, example embodiments relate to a multi-chip package including a plurality of stacked chips and a method of manufacturing the same.

### 2. Description of the Related Art

A high bandwidth memory (HBM) package may include a plurality of memory chips stacked on a logic chip in a vertical direction, and the memory chips may be bonded with each other by a bonding layer. If the bonding state between the memory chips is good, the HBM package may have enhanced performance.

### SUMMARY

Example embodiments provide a semiconductor package having enhanced electrical characteristics.

Example embodiments provide a method of manufacturing a semiconductor package having enhanced electrical characteristics.

According to example embodiments, there is provided a semiconductor package. The semiconductor package may include a buffer die and a memory die on the buffer die. The buffer die may include a first substrate having first and second surfaces at opposite sides, respectively, in a vertical direction, a through electrode extending through the first substrate and having a protrusion portion that protrudes beyond the second surface of the first substrate, a protective pattern on the second surface of the first substrate and covering a sidewall of the protrusion portion of the through electrode structure, a first conductive pad on the protective pattern and contacting an upper surface of the through electrode, and a filling pattern contacting an upper surface of the protective pattern and a sidewall of the first conductive pad and including an inorganic insulating material. The memory die may include a second substrate having first and second surfaces opposite to each other, respectively, in the vertical direction, and a second conductive pad and a conductive connection terminal sequentially stacked in the vertical direction beneath the first surface of the second substrate. The first conductive pad of the buffer die may contact the conductive connection terminal of the memory die.

According to example embodiments, there is provided a semiconductor package. The semiconductor package may include a first memory die and a second memory on the first memory die. The first memory die may include a first substrate having first and second surfaces opposite to each other, respectively, in a vertical direction, a first through electrode extending through the first substrate and having a first protrusion portion that protrudes beyond the second surface of the first substrate, a first protective pattern on the second surface of the first substrate and covering a sidewall of the first protrusion portion of the first through electrode, a first conductive pad on the first protective pattern and contacting an upper surface of the first through electrode, and a first filling pattern contacting an upper surface of the first protective pattern and a sidewall of the first conductive pad and including an inorganic insulating material. The second memory die may include a second substrate having first and second surfaces opposite to each other, respectively, in the vertical direction, and a second conductive pad and a conductive connection terminal sequentially stacked in the vertical direction beneath the first surface of the second substrate. The first conductive pad of the first memory die may contact the conductive connection terminal of the second memory die.

According to example embodiments, there is provided a method of manufacturing a semiconductor package. In the method, first and second semiconductor chips may be formed. In each of forming the first semiconductor chip and forming the second semiconductor chip, a first conductive pad and conductive connection terminal may be sequentially formed on a first surface of a substrate having the first surface and a second surface opposite to each other, respectively, in a vertical direction and including a through electrode extending through the substrate, a portion of the substrate adjacent to the second surface of the substrate may be removed to expose the through electrode, a second conductive pad may be formed on the second surface of the substrate to contact an upper surface of the through electrode, a filling pattern may be formed on the second surface of the substrate to cover a sidewall of the second conductive pad, and a bonding layer may be formed on the first surface of the substrate included in the second semiconductor chip to cover the first conductive pad and the conductive connection terminal of the second semiconductor chip. The first and second semiconductor chips may be thermally compressed so that the conductive connection terminal of the second semiconductor chip may contact the second conductive pad of the first semiconductor chip.

In the semiconductor package in accordance with example embodiments, no void may be formed in the bonding layer that may bond the stacked semiconductor chips with each other, and no electrical short may occur between the conductive connection terminals that may be disposed in the bonding layer and electrically connect the semiconductor chips with each other.

Additionally, the filling pattern including an inorganic insulating material having a relatively high thermal conductivity may be formed in the bonding layer including an organic material having a relatively low thermal conductivity, so as to enhance the heat dissipation characteristics.

### BRIEF DESCRIPTION OF THE DRAWINGS

FIG. 1 is a cross-sectional view illustrating a semiconductor package in accordance with example embodiments, FIG. 2 is an enlarged cross-sectional view of region X of FIG. 1, and FIG. 3 is an enlarged cross-sectional view of region Y of FIG. 1.

FIGS. 4 to 19 are cross-sectional views illustrating a method of manufacturing a semiconductor package in accordance with example embodiments.

FIGS. 20 and 21 are cross-sectional views illustrating semiconductor packages in accordance with example embodiments.

FIG. 22 is a cross-sectional view illustrating an electronic device in accordance with example embodiments.

### DETAILED DESCRIPTION OF EXAMPLE EMBODIMENTS

Hereinafter, example embodiments will be explained in detail with reference to the accompanying drawings.

It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of inventive concepts.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, a direction substantially parallel to an upper surface of a wafer or a substrate may be referred to as a horizontal direction, and a direction substantially perpendicular to the upper surface of the wafer or the substrate may be referred to as a vertical direction.

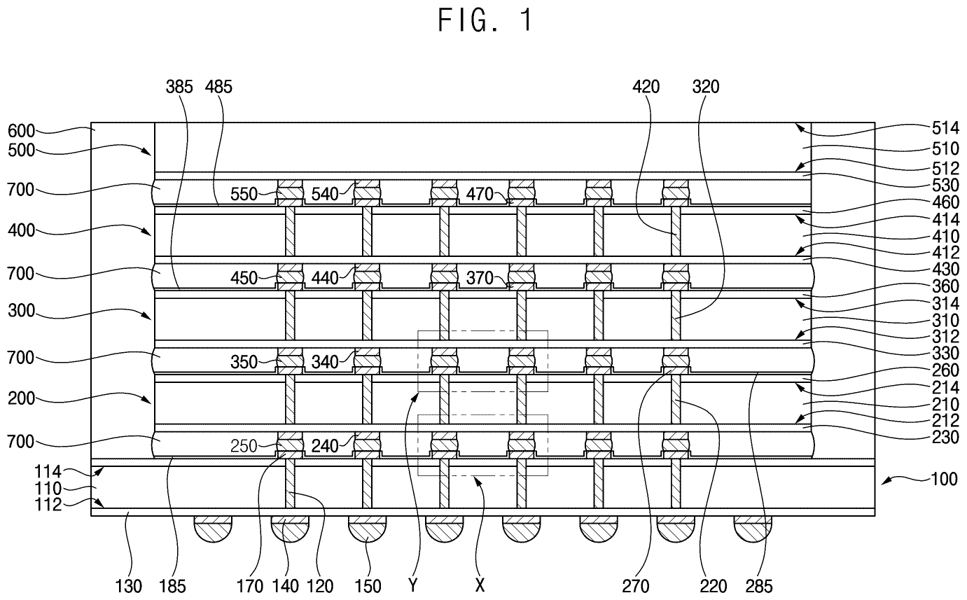

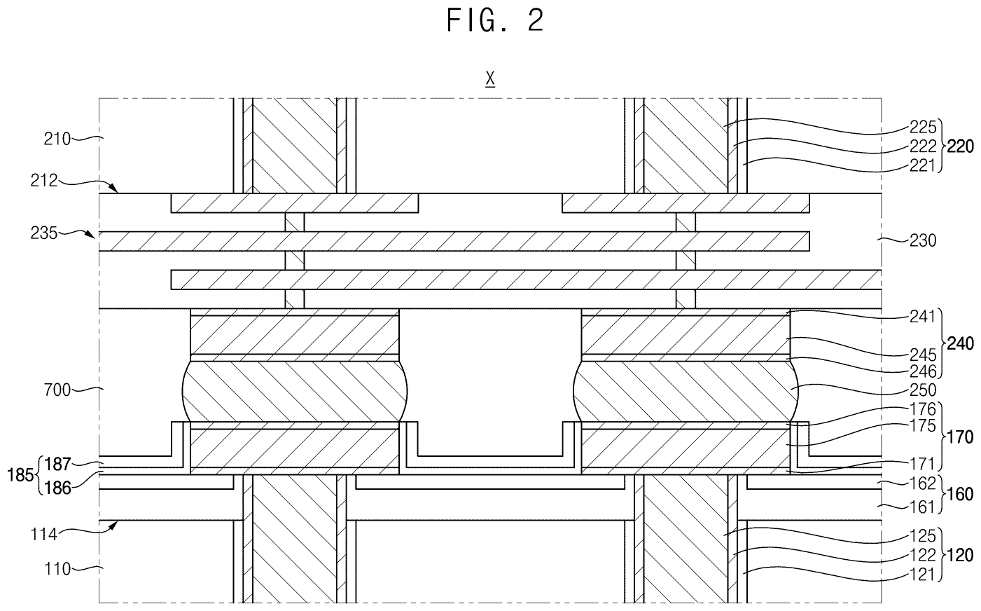

FIG. 1 is a cross-sectional view illustrating a semiconductor package in accordance with example embodiments, FIG. 2 is an enlarged cross-sectional view of region X of FIG. 1, and FIG. 3 is an enlarged cross-sectional view of region Y of FIG. 1.

Referring to FIGS. 1 to 3, the semiconductor package may include a first semiconductor chip 100, second to fifth semiconductor chips 200, 300, 400 and 500 sequentially stacked on the first semiconductor chip 100, a bonding layer 700 between the first to fifth semiconductor chips 100, 200, 300, 400 and 500, and a molding member on the first semiconductor chip 100 and covering sidewalls of the second to fifth semiconductor chips 200, 300, 400 and 500.

FIGS. 1 to 3 show that the semiconductor package includes four semiconductor chips 200, 300, 400 and 500 stacked on the first semiconductor chip 100, however, the inventive concept may not be limited thereto, and the semiconductor package may include more than four stacked semiconductor chips, e.g., eight or sixteen semiconductor chips. In example embodiments, the semiconductor package may be a high bandwidth memory (HBM) package.

In example embodiments, the first semiconductor chip 100 may be a buffer die, and may include a logic device, e.g., a controller. Each of the second to fifth semiconductor chips 200, 300, 400 and 500 may be a core die, and may include a volatile memory device, e.g., DRAM device, SRAM device, etc., or a non-volatile memory device, e.g., a flash memory device, EEPROM device, etc. Each of the second to fourth semiconductor chips 200, 300 and 400 may also be referred to as a middle core die, and the fifth semiconductor chip 500 may also be referred to as a top core die.

Additionally, the first semiconductor chip may also be referred to as a logic chip or logic die, and each of the second to fifth semiconductor chips 200, 300, 400 and 500 may also be referred to as a memory chip or a memory die.

The first semiconductor chip 100 may include a first substrate 110 having first and second surfaces 112 and 114 opposite to each other in the vertical direction, a first through electrode structure 120 extending through the first substrate 110, a first insulating interlayer and a second insulating interlayer 130 sequentially stacked in the vertical direction beneath the first surface 112 of the first substrate 110, a first conductive pad 140 beneath the second insulating interlayer 130, a first conductive connection member 150 beneath the first conductive pad 140, a first protective pattern structure 160 on the second surface 114 of the first substrate 110, a second conductive pad 170 on the first protective pattern structure 160 and contacting an upper surface of the first through electrode structure 120, and a first filling pattern structure 185 on an upper surface of the first protective pattern structure 160 and a sidewall of the second conductive pad 170.

The first substrate 110 may include a semiconductor material, e.g., silicon, germanium, silicon-germanium, or a III-V group compound semiconductor, e.g., GaP, GaAs, GaSb, etc. In example embodiments, the first substrate 110 may be a silicon-on-insulator (SOI) substrate or a germanium-on-insulator (GOI) substrate.

A circuit device, e.g., a logic device may be formed beneath the first surface 112 of the first substrate 110. The circuit device may include circuit patterns, which may be covered by the first insulating interlayer.

The second insulating interlayer 130 may contain a first wiring structure 135 (refer to FIG. 5) therein. The first wiring structure 135 may include, e.g., wirings, vias, contact plugs, etc.

The first insulating interlayer and the second insulating interlayer 130 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

The first conductive pad 140 may be disposed under the second insulating interlayer 130, and may contact the first wiring structure 135 to be electrically connected thereto. In example embodiments, a plurality of first conductive pads 140 may be spaced apart from each other in the horizontal direction.

In example embodiments, the first conductive pad 140 may include a first seed pattern 141 and first and second conductive patterns 145 and 146 sequentially stacked downwardly in the vertical direction from the second insulating interlayer 130. The first seed pattern 141 may include, e.g., titanium, and the first and second conductive patterns 145 and 146 may include, e.g., nickel and copper, respectively.

The first conductive connection member 150 may contact a lower surface of the first conductive pad 140. The first conductive connection member 150 may be a conductive connection terminal such as an external connection terminal and may be, e.g., a conductive bump. The first conductive connection member 150 may include a metal, e.g., tin, or solder that is a tin alloy such as tin/silver, tin/copper, tin/indium, tin/silver/copper, etc.

The first through electrode structure 120 may extend through the first substrate 110 in the vertical direction. A portion of the first through electrode structure 120, which may be referred to as a protrusion portion, may protrude upwardly in the vertical direction, and may be covered by the first protective pattern structure 160. A plurality of first through electrode structures 120 may be spaced apart from each other in the horizontal direction. In example embodiments, the first through electrode structure 120 may include a first through electrode 125 extending in the vertical direction, a first barrier pattern 122 covering a sidewall of the first through electrode 125, and a first insulation pattern 121 covering an outer sidewall of the first barrier pattern 122. However, in an example embodiment, the first insulation pattern 121 may not cover an upper portion of the outer sidewall of the first barrier pattern 122. The electrically conductive portion of each first through electrode structure 120 may be described herein as a through electrode.

The first through electrode 125 may include a metal, e.g., copper, aluminum, etc., the first barrier pattern 122 may include a metal nitride, e.g., titanium nitride, tantalum nitride, etc., and the first insulation pattern 121 may include an oxide, e.g., silicon oxide or an insulating nitride, e.g., silicon nitride.

In an example embodiment, the first through electrode structure 120 may extend through the first protective pattern structure 160, the first substrate 110 and the first insulating interlayer to contact the first wiring structure 135, and may be electrically connected to the first conductive pad 140 by the first wiring structure 135.

Alternatively, the first through electrode structure 120 may extend through the first protective pattern structure 160, the first substrate 110, the first insulating interlayer and the second insulating interlayer 130 to contact the first conductive pad 140, and may be electrically connected thereto. Alternatively, the first through electrode structure 120 may extend through the first protective pattern structure 160 and the first substrate 110 to contact one of the circuit patterns included in the circuit device covered by the first insulating interlayer, and may be electrically connected to the first conductive pad 140 by one of the circuit patterns and the first wiring structure 135.

The first protective pattern structure 160 may be formed on the second surface 114 of the first substrate 110, and may surround an upper portion of the first through electrode structure 120. In an example embodiment, the first protective pattern structure 160 may contact an outer sidewall of an upper portion of the first barrier pattern 122 of the first through electrode structure 120.

In example embodiments, the first protective pattern structure 160 may include a first protective pattern 161 and a second protective pattern 162 sequentially stacked in the vertical direction on the second surface 114 of the first substrate 110. Note that the first protective pattern structure 160 may also be described as a first protective pattern, and the first and second protective patterns 161 and 162 may be described as first and second protective sub-patterns, respectively. A portion of the first protective pattern 161 adjacent to the first through electrode structure 120 may protrude upwardly in the vertical direction, and an upper surface of the portion of the first protective pattern 161 may be substantially coplanar with an upper surface of the first through electrode structure 120. An outer sidewall of the portion of the first protective pattern 161 may be covered by the second protective pattern 162.

The first protective pattern 161 may include an oxide, e.g., silicon oxide, and the second protective pattern 162 may include an insulating nitride, e.g., silicon nitride.

The second conductive pad 170 may be electrically connected to the first conductive pad 140 by the first through electrode structure 120 and the first wiring structure 135. In example embodiments, a plurality of second conductive pads 170 may be spaced apart from each other in the horizontal direction.

In example embodiments, the second conductive pad 170 may include a second seed pattern and third and fourth conductive patterns 175 and 176 sequentially stacked upwardly in the vertical direction from the first protective pattern structure 160. The second seed pattern 171 may include, e.g., titanium, and the third and fourth conductive patterns 175 and 176 may include, e.g., nickel and gold, respectively.

In example embodiments, the first filling pattern structure 185 may be a filler or filling layer that covers an upper surface of a portion of the first protective pattern structure 160 between the second conductive pads 170 spaced apart from each other in the horizontal direction and a sidewall of each of the second conductive pads 170. Thus, a space between the second conductive pads 170 may be partially filled with the first filling pattern structure 185.

The first filling pattern structure 185 may include a first filling pattern 186 and a second filling pattern 187 sequentially stacked. The first filling pattern structure 185 may be described as a first filling pattern that includes a first filling sub-pattern 186 (or first filler) and a second filling sub-pattern 187 (or second filler). In example embodiments, a thickness of the second filling pattern 187 may be greater than a thickness of the first filling pattern 186. In some example embodiments, the first filling pattern 186 (e.g., the first filling sub-pattern) and/or the second filling pattern 187 (e.g., the second filling sub-pattern) is conformally formed on the respective surfaces. For example, the first filling pattern 186 (e.g., the first filling sub-pattern) and/or the second filling pattern 187 (e.g., the second filling sub-pattern) may have a constant thickness along a horizontal portion thereof.

In example embodiments, a cross-section in the vertical direction of a portion of the first filling pattern structure 185 adjacent to each of the second conductive pads 170 may have a shape of an “L,” and a cross-section in the vertical direction of a portion of each of the first and second filling patterns 186 and 187 included in the first filling pattern structure 185 adjacent to each of the second conductive pads 170 may also have a shape of an “L.” A cross-section in the vertical direction of a portion of the first filling pattern structure 185 between the second conductive pads 170 may have a shape of a “U,” e.g., a cup.

In example embodiments, uppermost surfaces of the first and second filling patterns 186 and 187 may be substantially coplanar with each other, and may be substantially coplanar with an upper surface of the second conductive pad 170.

Each of the first and second filling patterns 186 and 187 may include or be formed of an inorganic insulating material. In example embodiments, the first filling pattern 186 may include or may be an oxide, e.g., silicon oxide, and the second filling pattern 187 may include or may be an insulating nitride, e.g., silicon nitride. Thus, the second filling pattern 187 may have a thermal conductivity greater than a thermal conductivity of the first filling pattern 186.

The second semiconductor chip 200 may include a second substrate 210 having first and second surfaces 212 and 214 opposite to each other in the vertical direction, a second through electrode structure 220 extending through the second substrate 210, a third insulating interlayer and a fourth insulating interlayer 230 sequentially stacked in the vertical direction beneath the first surface 212 of the second substrate 210, a third conductive pad 240 beneath the fourth insulating interlayer 230, a second conductive connection member 250 (e.g., conductive connection terminal) beneath the third conductive pad 240, a second protective pattern structure 260 on the second surface 214 of the second substrate 210, a fourth conductive pad 270 on the second protective pattern structure 260 and contacting an upper surface of the second through electrode structure 220, and a second filling pattern structure 285 on an upper surface of the second protective pattern structure 260 and a sidewall of the fourth conductive pad 270.

The second substrate 210 may include a semiconductor material, e.g., silicon, germanium, silicon-germanium, or a III-V group compound semiconductor, e.g., GaP, GaAs, GaSb, etc. In example embodiments, the second substrate 210 may be a silicon-on-insulator (SOI) substrate or a germanium-on-insulator (GOI) substrate.

A circuit device, e.g., a volatile memory device such as DRAM device, SRAM device, etc., or a non-volatile memory device such as flash memory device, EEPROM device, etc., may be formed beneath the first surface 212 of the second substrate 210. The circuit device may include circuit patterns, which may be covered by the third insulating interlayer.

The fourth insulating interlayer 230 may contain a second wiring structure 235 therein. The second wiring structure 235 may include, e.g., wirings, vias, contact plugs, etc.

The third insulating interlayer and the fourth insulating interlayer 230 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

The third conductive pad 240 may be disposed under the fourth insulating interlayer 230, and may contact the second wiring structure 235 to be electrically connected thereto. In example embodiments, a plurality of third conductive pads 240 may be spaced apart from each other in the horizontal direction.

In example embodiments, the third conductive pad 240 may include a third seed pattern 241 and fifth and sixth conductive patterns 245 and 246 sequentially stacked downwardly in the vertical direction from the fourth insulating interlayer 230. The third seed pattern 241 may include, e.g., titanium, and the fifth and sixth conductive patterns 245 and 246 may include, e.g., nickel and copper, respectively.

The second conductive connection member 250 may contact an upper surface of the second conductive pad 170 and a lower surface of the third conductive pad 240. The second conductive connection member 250 may be, e.g., a conductive bump. The second conductive connection member 150 may include a metal, e.g., tin, or solder.

The second through electrode structure 220 may extend through the second substrate 210 in the vertical direction. A portion of the second through electrode structure 220, which may be referred to as a protrusion portion, may protrude upwardly in the vertical direction, and may be covered by the second protective pattern structure 260. A plurality of second through electrode structures 220 may be spaced apart from each other in the horizontal direction. In example embodiments, the second through electrode structure 220 may include a second through electrode 225 extending in the vertical direction, a second barrier pattern 222 covering a sidewall of the second through electrode 225, and a second insulation pattern 221 covering an outer sidewall of the second barrier pattern 222. However, in an example embodiment, the second insulation pattern 221 may not cover an upper portion of the outer sidewall of the second barrier pattern 222. The electrically conductive portion of each second through electrode structure 220 may be described herein as a through electrode.

The second through electrode 225 may include a metal, e.g., copper, aluminum, etc., the second barrier pattern 222 may include a metal nitride, e.g., titanium nitride, tantalum nitride, etc., and the second insulation pattern 221 may include an oxide, e.g., silicon oxide or an insulating nitride, e.g., silicon nitride.

In an example embodiment, the second through electrode structure 220 may extend through the second protective pattern structure 260, the second substrate 210 and the third insulating interlayer to contact the second wiring structure 235, and may be electrically connected to the third conductive pad 240 by the second wiring structure 235.

Alternatively, the second through electrode structure 220 may extend through the second protective pattern structure 260, the second substrate 210 and the third insulating interlayer and the fourth insulating interlayer 230 to contact the third conductive pad 240, and may be electrically connected thereto. Alternatively, the second through electrode structure 220 may extend through the second protective pattern structure 260 and the second substrate 210 to contact one of the circuit patterns included in the circuit device covered by the third insulating interlayer, and may be electrically connected to the third conductive pad 240 by one of the circuit patterns and the second wiring structure 235.

The second protective pattern structure 260 may be formed on the second surface 214 of the second substrate 210, and may surround an upper portion of the second through electrode structure 220. In an example embodiment, the second protective pattern structure 260 may contact an outer sidewall of an upper portion of the second barrier pattern 222 of the second through electrode structure 220.

In example embodiments, the second protective pattern structure 260 may include a third protective pattern 261 and a fourth protective pattern 262 sequentially stacked in the vertical direction on the second surface 214 of the second substrate 210. A portion of the third protective pattern 261 adjacent to the second through electrode structure 220 may protrude upwardly in the vertical direction, and an upper surface of the portion of the second protective pattern 261 may be substantially coplanar with an upper surface of the second through electrode structure 220. An outer sidewall of the portion of the third protective pattern 261 may be covered by the fourth protective pattern 262.

The third protective pattern 261 may include an oxide, e.g., silicon oxide, and the fourth protective pattern 262 may include an insulating nitride, e.g., silicon nitride.

The fourth conductive pad 270 may be electrically connected to the third conductive pad 240 by the second through electrode structure 220 and the second wiring structure 235. In example embodiments, a plurality of fourth conductive pads 270 may be spaced apart from each other in the horizontal direction.

In example embodiments, the fourth conductive pad 270 may include a fourth seed pattern 271 and seventh and eighth conductive patterns 275 and 276 sequentially stacked upwardly in the vertical direction from the second protective pattern structure 260. The fourth seed pattern 271 may include, e.g., titanium, and the seventh and eighth conductive patterns 275 and 276 may include, e.g., nickel and gold, respectively.

In example embodiments, the second filling pattern structure 285 may be a filler or filling layer that covers an upper surface of a portion of the second protective pattern structure 260 between the fourth conductive pads 270 spaced apart from each other in the horizontal direction and a sidewall of each of the fourth conductive pads 270. Thus, a space between the fourth conductive pads 270 may be partially filled with the second filling pattern structure 285.

The second filling pattern structure 285 may include a third filling pattern 286 and a fourth filling pattern 287 sequentially stacked. The second filling pattern structure 285 may be described as a second filling pattern that includes a third filling sub-pattern 286 (or third filler) and a fourth filling sub-pattern 287 (or fourth filler). In example embodiments, a cross-section in the vertical direction of a portion of the second filling pattern structure 285 adjacent to each of the fourth conductive pads 270 may have a shape of an “L,” and a cross-section in the vertical direction of a portion of each of the third and fourth filling patterns 286 and 287 included in the second filling pattern structure 285 adjacent to each of the fourth conductive pads 270 may also have a shape of an “L.” A cross-section in the vertical direction of a portion of the second filling pattern structure 285 between the fourth conductive pads 270 may have a shape of a “U,” e.g., a cup.

In example embodiments, uppermost surfaces of the third and fourth filling patterns 286 and 287 may be substantially coplanar with each other, and may be substantially coplanar with an upper surface of the fourth conductive pad 270.

Each of the third and fourth filling patterns 286 and 287 may include an inorganic insulating material. In example embodiments, the third filling pattern 286 may include an oxide, e.g., silicon oxide, and the fourth filling pattern 287 may include an insulating nitride, e.g., silicon nitride.

The bonding layer 700 be disposed between the first and second semiconductor chips 100 and 200, and may bond the first and second semiconductor chips 100 and 200 with each other. The bonding layer 700 may surround the second and third conductive pads 170 and 240 and the second conductive connection member 250. The bonding layer 700 may include a non-conductive film (NCF), e.g., thermosetting resin.

The third to fifth semiconductor chips 300, 400 and 500 may be sequentially stacked in the vertical direction on the second semiconductor chip 200, and the bonding layer 700 may be disposed therebetween.

Each of the third to fifth semiconductor chips 300, 400 and 500 may have a structure substantially the same as or similar to that of the second semiconductor chip 200, and thus the third to fifth semiconductor chips 300, 400 and 500 are described briefly herein.

The third semiconductor chip 300 may include a third substrate 310 having first and second surfaces 312 and 314 opposite to each other in the vertical direction, a third through electrode structure 320 extending through the third substrate 310, a fifth insulating interlayer and a sixth insulating interlayer 330 sequentially stacked in the vertical direction beneath the first surface 312 of the third substrate 310, a fifth conductive pad 340 beneath the sixth insulating interlayer 330, a third conductive connection member 350 (e.g., conductive connection terminal) beneath the fifth conductive pad 340, a third protective pattern structure 360 on the second surface 314 of the third substrate 310, a sixth conductive pad 370 on the third protective pattern structure 360 and contacting an upper surface of the third through electrode structure 320, and a third filling pattern structure 385 on an upper surface of the third protective pattern structure 360 and a sidewall of the sixth conductive pad 370.

A circuit device, e.g., a memory device may be formed beneath the first surface 312 of the third substrate 310. The circuit device may include circuit patterns, which may be covered by the fifth insulating interlayer. The sixth insulating interlayer 330 may contain a third wiring structure 335 therein.

The fifth conductive pad 340 may be disposed under the sixth insulating interlayer 330, and may contact the third wiring structure 335 to be electrically connected thereto. In example embodiments, a plurality of fifth conductive pads 340 may be spaced apart from each other in the horizontal direction.

In example embodiments, the fifth conductive pad 340 may include a fifth seed pattern 341 and ninth and tenth conductive patterns 345 and 346 sequentially stacked downwardly in the vertical direction from the sixth insulating interlayer 330. The fifth seed pattern 341 may include, e.g., titanium, and the ninth and tenth conductive patterns 345 and 346 may include, e.g., nickel and copper, respectively.

The third conductive connection member 350 may contact an upper surface of the fourth conductive pad 270 and a lower surface of the fifth conductive pad 340.

The third through electrode structure 320 may extend through the third substrate 310 in the vertical direction. A portion of the third through electrode structure 320, which may be referred to as a protrusion portion, may protrude upwardly in the vertical direction, and may be covered by the third protective pattern structure 360. A plurality of third through electrode structures 320 may be spaced apart from each other in the horizontal direction. In example embodiments, the third through electrode structure 320 may include a third through electrode 325 extending in the vertical direction, a third barrier pattern 322 covering a sidewall of the third through electrode 325, and a third insulation pattern 321 covering an outer sidewall of the third barrier pattern 322. However, in an example embodiment, the third insulation pattern 321 may not cover an upper portion of the outer sidewall of the third barrier pattern 322. The electrically conductive portion of each third through electrode structure 320 may be described herein as a through electrode

In an example embodiment, the third through electrode structure 320 may extend through the third protective pattern structure 360, the third substrate 310 and the fifth insulating interlayer to contact the third wiring structure 335, and may be electrically connected to the fifth conductive pad 340 by the third wiring structure 335.

The third protective pattern structure 360 may be formed on the second surface 314 of the third substrate 310, and may surround an upper portion of the third through electrode structure 320. In an example embodiment, the third protective pattern structure 360 may contact an outer sidewall of an upper portion of the third barrier pattern 322 of the third through electrode structure 320.

In example embodiments, the third protective pattern structure 360 may include a fifth protective pattern and a sixth protective pattern sequentially stacked in the vertical direction on the second surface 314 of the third substrate 310. A portion of the fifth protective pattern adjacent to the third through electrode structure 320 may protrude upwardly in the vertical direction, and an upper surface of the portion of the fifth protective pattern may be substantially coplanar with an upper surface of the third through electrode structure 320. An outer sidewall of the portion of the fifth protective pattern may be covered by the sixth protective pattern.

The fifth protective pattern may include an oxide, e.g., silicon oxide, and the sixth protective pattern may include an insulating nitride, e.g., silicon nitride.

The sixth conductive pad 370 may be electrically connected to the fifth conductive pad 340 by the third through electrode structure 320 and the third wiring structure 335. In example embodiments, the sixth conductive pad 370 may include a sixth seed pattern and eleventh and twelfth conductive patterns sequentially stacked upwardly in the vertical direction from the third protective pattern structure 360. The sixth seed pattern may include, e.g., titanium, and the eleventh and twelfth conductive patterns may include, e.g., nickel and gold, respectively.

In example embodiments, the third filling pattern structure 385 may be a filler or filling layer that covers an upper surface of a portion of the third protective pattern structure 360 between the sixth conductive pads 370 spaced apart from each other in the horizontal direction and a sidewall of each of the sixth conductive pads 370. Thus, a space between the sixth conductive pads 370 may be partially filled with the third filling pattern structure 385.

The third filling pattern structure 385 may include a fifth filling pattern and a sixth filling pattern sequentially stacked. In example embodiments, a cross-section in the vertical direction of a portion of the third filling pattern structure 385 adjacent to each of the sixth conductive pads 370 may have a shape of an “L,” and a cross-section in the vertical direction of a portion of each of the fifth and sixth filling patterns included in the third filling pattern structure 385 adjacent to each of the sixth conductive pads 370 may also have a shape of an “L.” A cross-section in the vertical direction of a portion of the third filling pattern structure 385 between the sixth conductive pads 370 may have a shape of a “U,” e.g., a cup.

In example embodiments, uppermost surfaces of the fifth and sixth filling patterns may be substantially coplanar with each other, and may be substantially coplanar with an upper surface of the sixth conductive pad 370.

Each of the fifth and sixth filling patterns may include an inorganic insulating material. In example embodiments, the fifth filling pattern may include an oxide, e.g., silicon oxide, and the sixth filling pattern may include an insulating nitride, e.g., silicon nitride.

The bonding layer 700 may be disposed between the second and third semiconductor chips 200 and 300, and may surround the fourth and fifth conductive pads 270 and 340 and the third conductive connection member 350.

The fourth semiconductor chip 400 may include a fourth substrate 410 having first and second surfaces 412 and 414 opposite to each other in the vertical direction, a fourth through electrode structure 420 extending through the fourth substrate 410, a seventh insulating interlayer and an eighth insulating interlayer 430 sequentially stacked in the vertical direction beneath the first surface 412 of the fourth substrate 410, a seventh conductive pad 440 beneath the eighth insulating interlayer 430, a fourth conductive connection member 450 (e.g., conductive connection terminal) beneath the seventh conductive pad 440, a fourth protective pattern structure 460 on the second surface 414 of the fourth substrate 410, an eighth conductive pad 470 on the fourth protective pattern structure 460 and contacting an upper surface of the fourth through electrode structure 420, and a fourth filling pattern structure 485 on an upper surface of the fourth protective pattern structure 460 and a sidewall of the eighth conductive pad 470.

A circuit device, e.g., a memory device, may be formed beneath the first surface 412 of the fourth substrate 410. The circuit device may include circuit patterns, which may be covered by the seventh insulating interlayer. The eighth insulating interlayer 430 may contain a fourth wiring structure therein.

The seventh conductive pad 440 may be disposed under the eighth insulating interlayer 430, and may contact the fourth wiring structure to be electrically connected thereto. In example embodiments, a plurality of seventh conductive pads 440 may be spaced apart from each other in the horizontal direction.

In example embodiments, the seventh conductive pad 440 may include a seventh seed pattern and thirteenth and fourteenth conductive patterns sequentially stacked downwardly in the vertical direction from the eighth insulating interlayer 430. The seventh seed pattern may include, e.g., titanium, and the thirteenth and fourteenth conductive patterns may include, e.g., nickel and copper, respectively.

The fourth conductive connection member 450 may contact an upper surface of the sixth conductive pad 370 and a lower surface of the seventh conductive pad 440.

The fourth through electrode structure 420 may extend through the fourth substrate 410 in the vertical direction. A portion of the fourth through electrode structure 420, which may be referred to as a protrusion portion, may protrude upwardly in the vertical direction, and may be covered by the fourth protective pattern structure 460. A plurality of fourth through electrode structures 420 may be spaced apart from each other in the horizontal direction. In example embodiments, the fourth through electrode structure 420 may include a fourth through electrode extending in the vertical direction, a fourth barrier pattern covering a sidewall of the fourth through electrode, and a fourth insulation pattern covering an outer sidewall of the fourth barrier pattern. However, in an example embodiment, the fourth insulation pattern may not cover an upper portion of the outer sidewall of the fourth barrier pattern.

In an example embodiment, the fourth through electrode structure 420 may extend through the fourth protective pattern structure 460, the fourth substrate 410 and the seventh insulating interlayer to contact the fourth wiring structure, and may be electrically connected to the seventh conductive pad 440 by the fourth wiring structure.

The fourth protective pattern structure 460 may be formed on the second surface 414 of the fourth substrate 410, and may surround an upper portion of the fourth through electrode structure 420. In an example embodiment, the fourth protective pattern structure 460 may contact an outer sidewall of an upper portion of the fourth barrier pattern of the fourth through electrode structure 420.

In example embodiments, the fourth protective pattern structure 460 may include a seventh protective pattern and an eighth protective pattern sequentially stacked in the vertical direction on the second surface 414 of the fourth substrate 410. A portion of the seventh protective pattern adjacent to the fourth through electrode structure 420 may protrude upwardly in the vertical direction, and an upper surface of the portion of the seventh protective pattern may be substantially coplanar with an upper surface of the fourth through electrode structure 420. An outer sidewall of the portion of the seventh protective pattern may be covered by the eighth protective pattern.

The seventh protective pattern may include an oxide, e.g., silicon oxide, and the eighth protective pattern may include an insulating nitride, e.g., silicon nitride.

The eighth conductive pad 470 may be electrically connected to the seventh conductive pad 440 by the fourth through electrode structure 420 and the fourth wiring structure. In example embodiments, a plurality of eighth conductive pads 470 may be spaced apart from each other in the horizontal direction. In example embodiments, the eighth conductive pad 470 may include an eighth seed pattern and fifteenth and sixteenth conductive patterns sequentially stacked upwardly in the vertical direction from the fourth protective pattern structure 460. The eighth seed pattern may include, e.g., titanium, and the fifteenth and the sixteenth conductive patterns may include, e.g., nickel and gold, respectively.

In example embodiments, the fourth filling pattern structure 485 may be a filler or filling layer that covers an upper surface of a portion of the fourth protective pattern structure 460 between the eighth conductive pads 470 spaced apart from each other in the horizontal direction and a sidewall of each of the eighth conductive pads 470. Thus, a space between the eighth conductive pads 470 may be partially filled with the fourth filling pattern structure 485.

The fourth filling pattern structure 485 may include a seventh filling pattern and an eighth filling pattern sequentially stacked. In example embodiments, a cross-section in the vertical direction of a portion of the fourth filling pattern structure 485 adjacent to each of the eighth conductive pads 470 may have a shape of an “L,” and a cross-section in the vertical direction of a portion of each of the seventh and eighth filling patterns included in the fourth filling pattern structure 485 adjacent to each of the eighth conductive pads 470 may also have a shape of an “L.” A cross-section in the vertical direction of a portion of the fourth filling pattern structure 485 between the eighth conductive pads 470 may have a shape of a “U,” e.g., a cup.

In example embodiments, uppermost surfaces of the seventh and eighth filling patterns may be substantially coplanar with each other, and may be substantially coplanar with an upper surface of the eighth conductive pad 470.

Each of the seventh and eighth filling patterns may include an inorganic insulating material. In example embodiments, the seventh filling pattern may include an oxide, e.g., silicon oxide, and the eighth filling pattern may include an insulating nitride, e.g., silicon nitride.

The bonding layer 700 may be disposed between the third and fourth semiconductor chips 300 and 400, and may surround the sixth and seventh conductive pads 370 and 440 and the fourth conductive connection member 450.

The fifth semiconductor chip 500 may include a fifth substrate 510 having first and second surfaces 512 and 514 opposite to each other in the vertical direction, a ninth insulating interlayer and a tenth insulating interlayer 530 sequentially stacked in the vertical direction beneath the first surface 512 of the fifth substrate 510, a ninth conductive pad 540 beneath the tenth insulating interlayer 530 and a fifth conductive connection member 550 (e.g., conductive connection terminal) beneath the ninth conductive pad 540.

A circuit device, e.g., a memory device, may be formed beneath the first surface 512 of the fifth substrate 510. The circuit device may include circuit patterns, which may be covered by the ninth insulating interlayer. The tenth insulating interlayer 530 may contain a fifth wiring structure therein.

The ninth conductive pad 540 may be disposed under the tenth insulating interlayer 530, and may contact the fifth wiring structure to be electrically connected thereto. In example embodiments, a plurality of ninth conductive pads 540 may be spaced apart from each other in the horizontal direction.

In example embodiments, the ninth conductive pad 540 may include a ninth seed pattern and seventeenth and eighteenth conductive patterns sequentially stacked downwardly in the vertical direction from the tenth insulating interlayer 530. The ninth seed pattern may include, e.g., titanium, and the seventeenth and eighteenth conductive patterns may include, e.g., nickel and copper, respectively.

The fifth conductive connection member 550 may contact an upper surface of the eighth conductive pad 470 and a lower surface of the ninth conductive pad 540.

The bonding layer 700 may be disposed between the fourth and fifth semiconductor chips 400 and 500, and may bond the fourth and fifth semiconductor chips 400 and 500 with each other, and may surround the eighth and ninth conductive pads 470 and 540 and the fifth conductive connection member 550.

The first to fifth semiconductor chips 100, 200, 300, 400 and 500 may be electrically connected to each other by the first to fourth through electrodes 120, 220, 320 and 420 extending through the first to fourth substrates 110, 210, 310 and 410, respectively, the first to third wiring structures 135, 235 and 335 and the fourth and fifth wiring structures electrically connected thereto, the first to ninth conductive pads 140, 170, 240, 270, 340, 370, 440, 470 and 540 electrically connected thereto, and the second to fifth conductive connection members 250, 350, 450 and 550 electrically connected thereto. Accordingly, electrical signals, e.g., data signals, control signals, etc., may be transferred among the first to fifth semiconductor chips 100, 200, 300, 400 and 500.

Likewise, electrical signals may be transferred from the first conductive pad 140 to an external device through the first conductive connection member 150.

The molding member 600 may cover sidewalls of the second to fifth semiconductor chips 200, 300, 400 and 500 on the first semiconductor chip 100, and an upper surface of the molding member 600 may be substantially coplanar with an upper surface of the fifth semiconductor chip 500. The molding member 600 may include a polymer, e.g., epoxy molding compound (EMC).

In the semiconductor package, the first to fifth semiconductor chips 100, 200, 300, 400 and 500 may communicate with each other through the second to fifth conductive connection members 250, 350, 450 and 550. For example, the second conductive connection member 250 may be disposed between and contact the second and third conductive pads 170 and 240 of the first and second semiconductor chips 100 and 200, respectively, and thus the second conductive connection member 250 may serve as an electrical signal path. Similarly, the third conductive connection member 350 may be disposed between and contact the fourth and fifth conductive pads 270 and 340 of the second and third semiconductor chips 200 and 300, respectively, and thus may serve as an electrical signal path.

In the semiconductor package, each of the bonding layers 700 may surround a corresponding one of the second to fifth conductive connection members 250, 350, 450 and 550, and may be disposed between neighboring ones of the first to fifth semiconductor chips 100, 200, 300, 400 and 500 to bond the first to fifth semiconductor chips 100, 200, 300, 400 and 500 with each other.

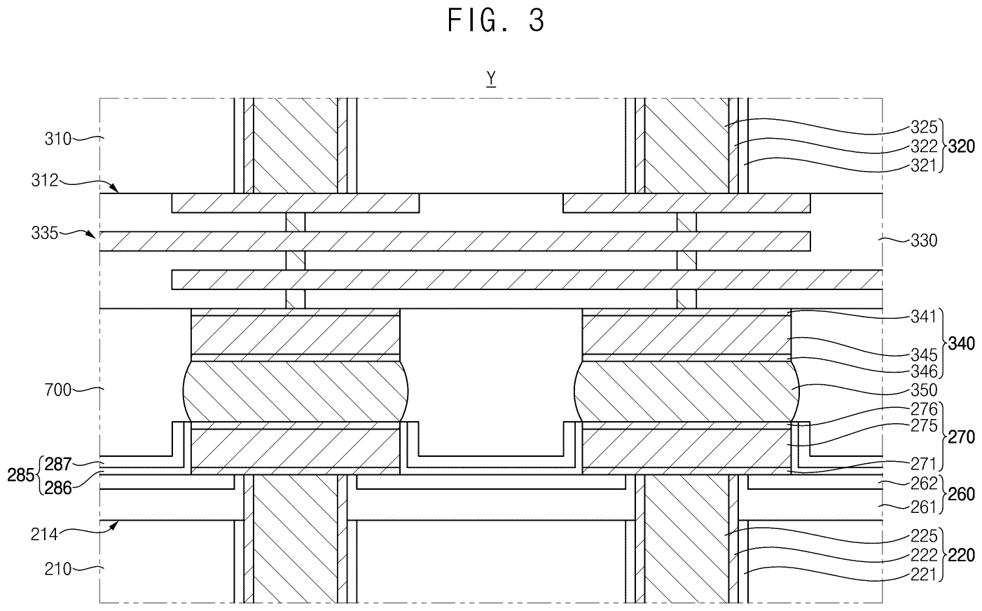

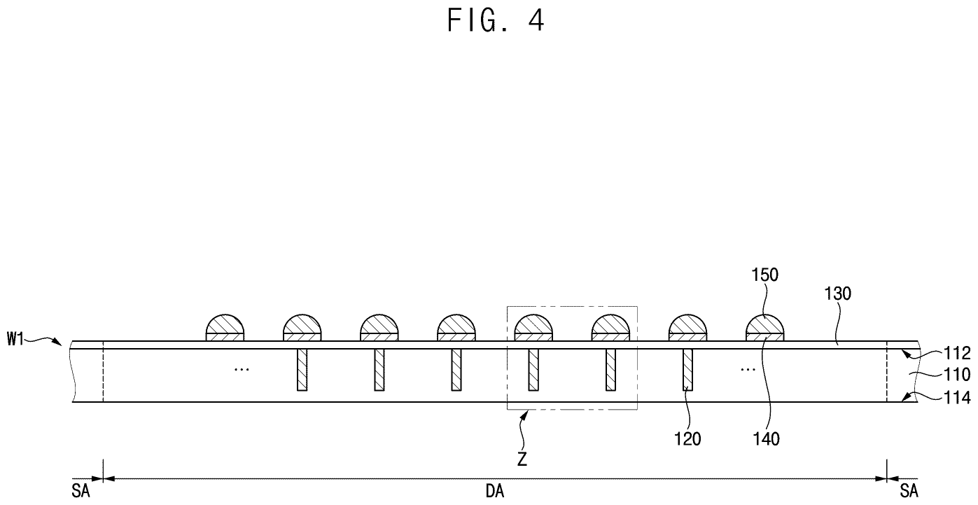

As illustrated below with reference to FIGS. 4 to 19, the first to fifth semiconductor chips 100, 200, 300, 400 and 500 may be bonded with each other by a thermal compression bonding (TCB) process. In some HBM packages, if an amount of the bonding layer between semiconductor chips is not sufficient, a void may be generated in the bonding layer. Thus, during the TCB process, conductive connection members at each level between semiconductor chips may move into the void, and an electrical short may occur between neighboring ones of the conductive connection members.

However, in example embodiments of the disclosed semiconductor package and methods of manufacturing thereof, the first to fourth semiconductor chips 100, 200, 300 and 400 may include the first to fourth filling pattern structures 185, 285, 385 and 485 that may be disposed on respective portions of the first to fourth protective pattern structures 160, 260, 360 and 460 between the second, fourth, sixth and eighth conductive pads 170, 270, 370 and 470, and cover sidewalls of the second, fourth, sixth and eighth conductive pads 170, 270, 370 and 470.

Thus, spaces between neighboring ones of the second, fourth, sixth and eighth conductive pads 170, 270, 370 and 470 may be partially filled with the first to fourth filling pattern structures 185, 285, 385 and 485 so as to prevent the generation of the void in the bonding layer 700 during the TCB process, and the electrical short between neighboring ones of the second to fifth conductive connection members 250, 350, 450 and 550 may be prevented. Accordingly, the disclosed semiconductor package and methods can improve over other HBM packages by preventing electrical shorts.

Additionally, each of the first to fourth filling pattern structures 185, 285, 385 and 485 including the inorganic insulating material may have a thermal conductivity greater than that of, e.g., an NCF included in the bonding layer 700, and each of the second and fourth filling patterns 187 and 287 and the sixth and eighth filling patterns, which have a relatively high thermal conductivity, may have a volume greater than that of a corresponding one of the first and third filling patterns 186 and 286 and the fifth and seventh filling patterns having a relatively low thermal conductivity.

Thus, the heat dissipation characteristics of the semiconductor package including the first to fourth filling pattern structures 185, 285, 385 and 485 may be enhanced.

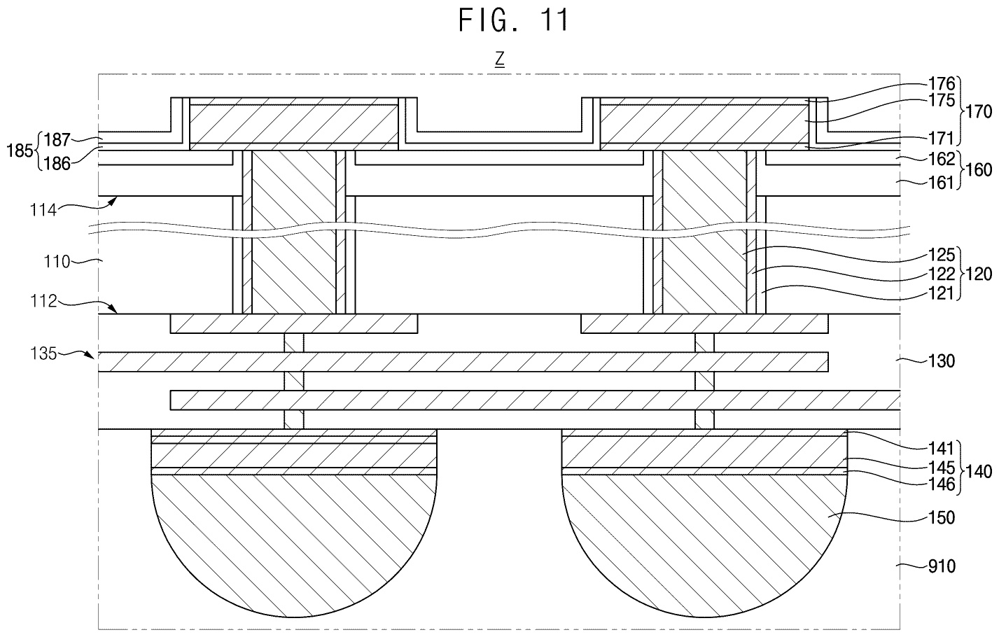

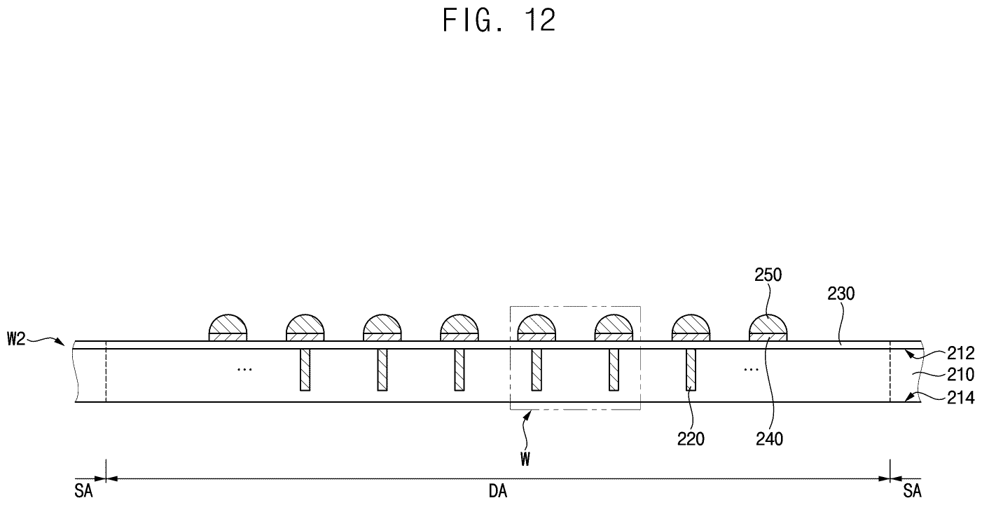

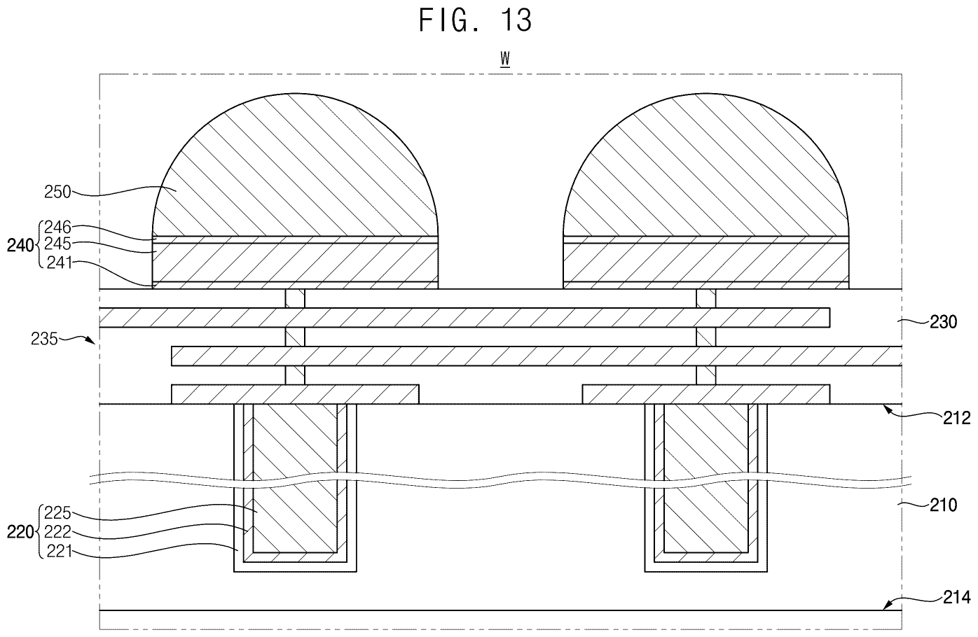

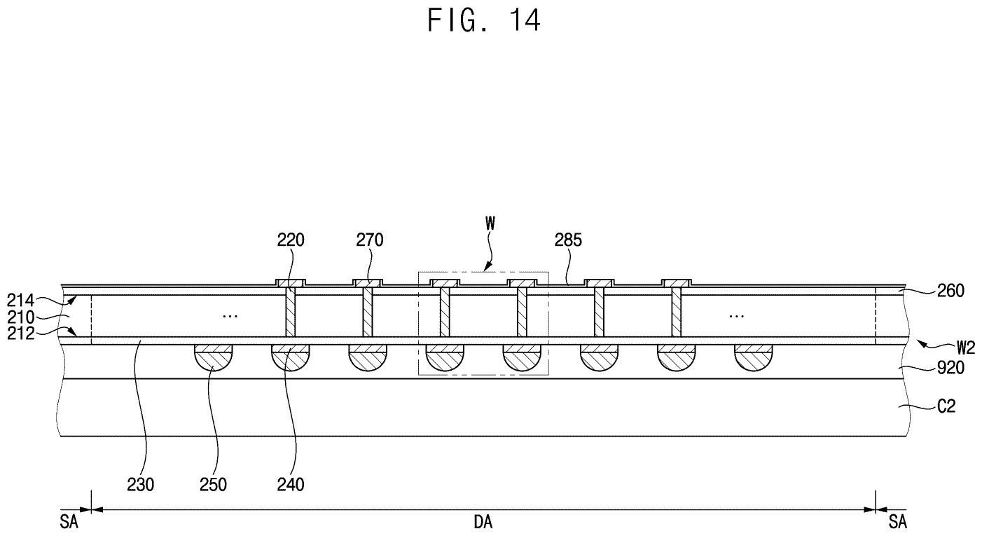

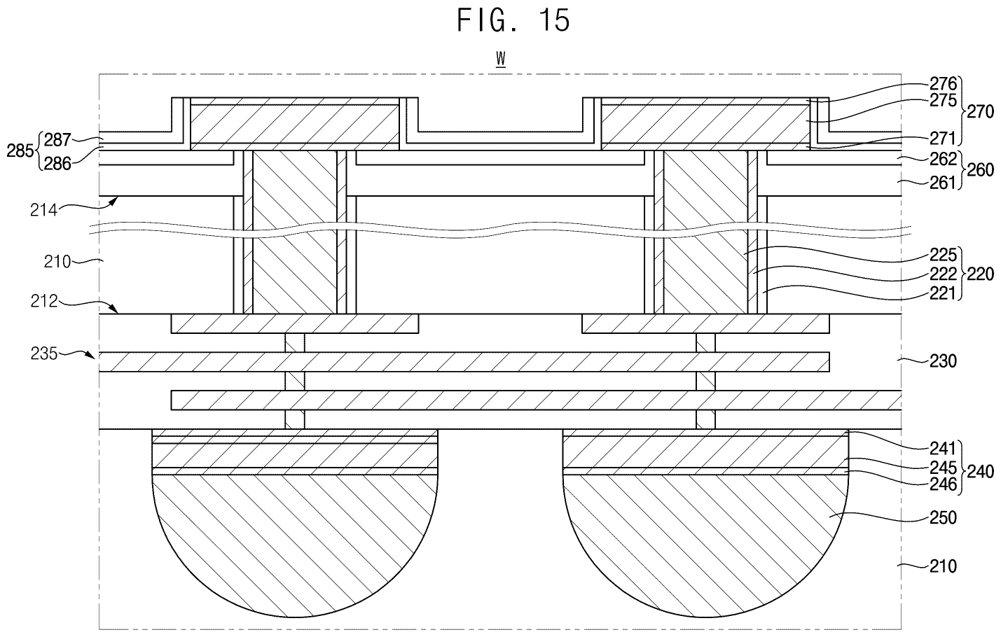

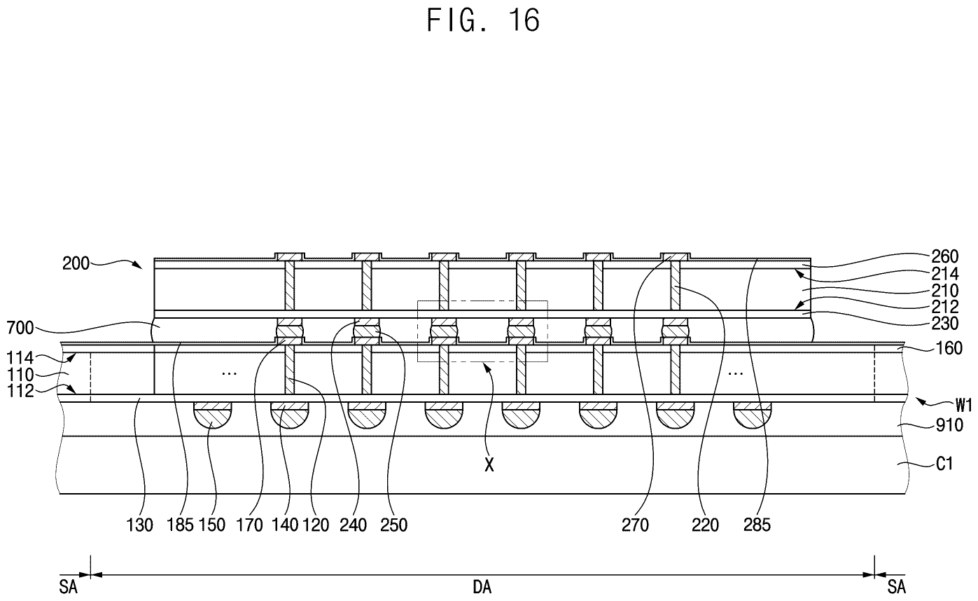

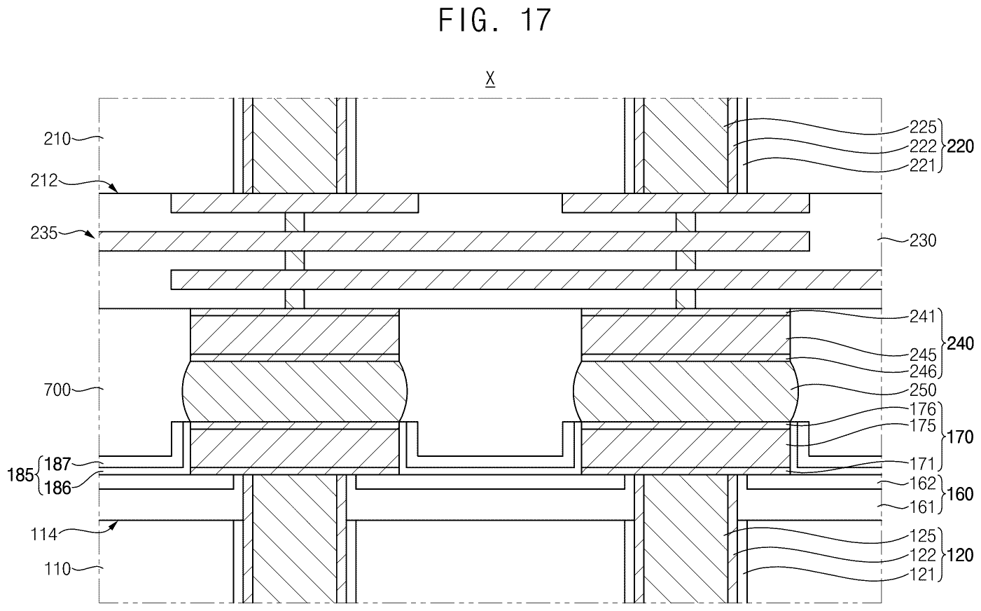

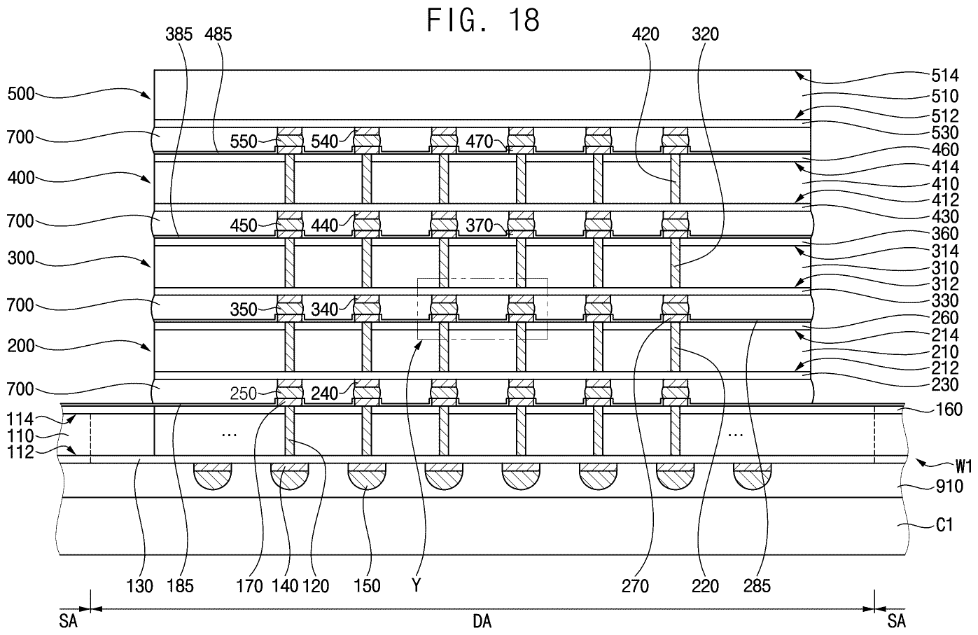

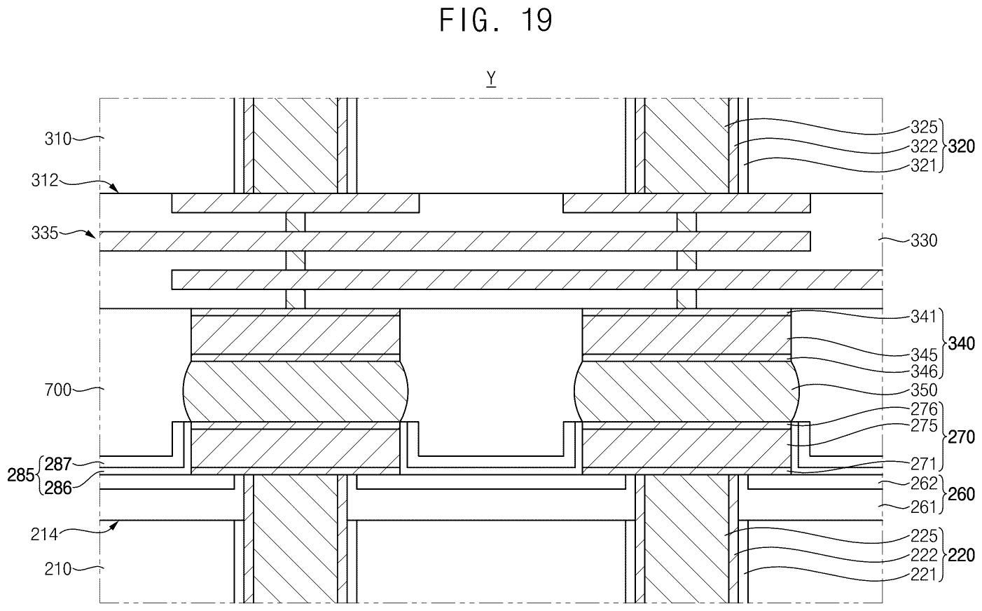

FIGS. 4 to 19 are cross-sectional views illustrating a method of manufacturing a semiconductor package in accordance with example embodiments. FIGS. 5, 7-9 and 11 are enlarged cross-sectional views of region Z of FIGS. 4, 6 and 10, respectively, FIGS. 13 and 15 are enlarged cross-sectional views of region W of FIGS. 12 and 14, respectively, FIG. 17 is an enlarged cross-sectional view of region X of FIG. 16, and FIG. 19 is an enlarged cross-sectional view of region Y of FIG. 18.

Referring to FIGS. 4 and 5, a first wafer W1 may be provided.

In example embodiments, the first wafer W1 may include a first substrate 110 having first and second surfaces 112 and 114 opposite to each other in the vertical direction. Additionally, the first wafer W1 may include a plurality of die regions DA and a scribe lane region SA surrounding each of the die regions DA. The first wafer W1 may be cut along the scribe lane region SA by a sawing process to be singulated into a plurality of first semiconductor chips.

In the die region DA, a circuit device may be formed on the first surface 112 of the first substrate 110. The circuit device may include a logic device. The circuit device may include circuit patterns, and a first insulating interlayer may be formed on the first surface 112 of the first substrate 110 to cover the circuit patterns.

A second insulating interlayer 130 may be formed on the first insulating interlayer, and may contain a first wiring structure 135 therein. The first wiring structure 135 may include, e.g., wirings, vias, contact plugs, etc.

A first conductive pad 140 may be formed on the second insulating interlayer 130 to contact the first wiring structure 135, so as to be electrically connected thereto. In example embodiments, a plurality of first conductive pads 140 may be spaced apart from each other in the horizontal direction.

In an example embodiment, the first conductive pad 140 may be formed by the following processes.

Particularly, a first seed layer may be formed on the second insulating interlayer 130, a first photoresist pattern including a first opening partially exposing an upper surface of the first seed layer may be formed on the first seed layer, and an electroplating process or an electroless plating process may be performed to form first and second conductive patterns 145 and 146 in the first opening.

The first photoresist pattern may be removed by, e.g., an ashing process and/or a stripping process to expose a portion of the first seed layer. The exposed portion of the first seed layer may be removed to form a first seed pattern 141 under the first conductive pattern 145.

Thus, the first conductive pad 140 including the first seed pattern 141 and the first and second conductive patterns 145 and 146 sequentially stacked in the vertical direction may be formed.

A first conductive connection member 150 may be formed on the first conductive pad 140.

In an example embodiment, the first conductive connection member 150 may be formed by the following processes.

Particularly, a second photoresist pattern including a second opening exposing an upper surface of the first conductive pad 140 may be formed on the second insulating interlayer 130. An electroplating process or an electroless plating process may be performed to form a preliminary first conductive connection member in the second opening. After removing the second photoresist pattern, a reflow process may be performed so that the preliminary first conductive connection member may be transformed into a first conductive connection member 150.

In example embodiments, the first conductive connection member 150 may have, e.g., a hemispherical shape or a semioval shape.

In example embodiments, a first through electrode structure 120 extending in the vertical direction through an upper portion of the first substrate 110 may be formed. For example, a portion of the first substrate 110 adjacent to the first surface 112 thereof may be formed. In example embodiments, a plurality of first through electrode structures 120 may be spaced apart from each other in the horizontal direction.

In an example embodiment, the first through electrode structure 120 may include a first through electrode 125 extending in the vertical direction, a first barrier pattern 122 covering a sidewall and a lower surface of the first through electrode 125, and a first insulation pattern 121 covering a sidewall and a lower surface of the first barrier pattern 122.

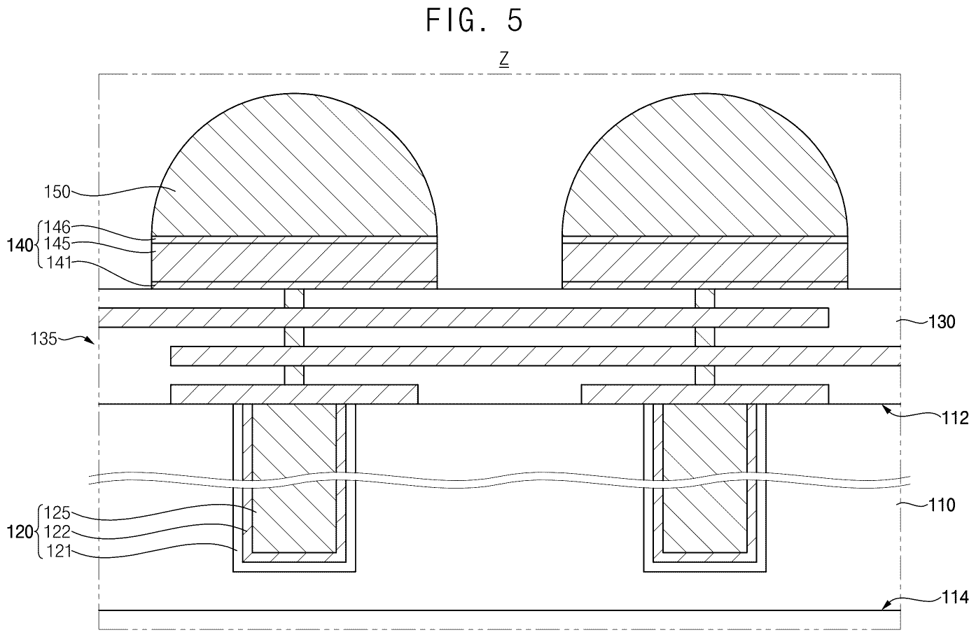

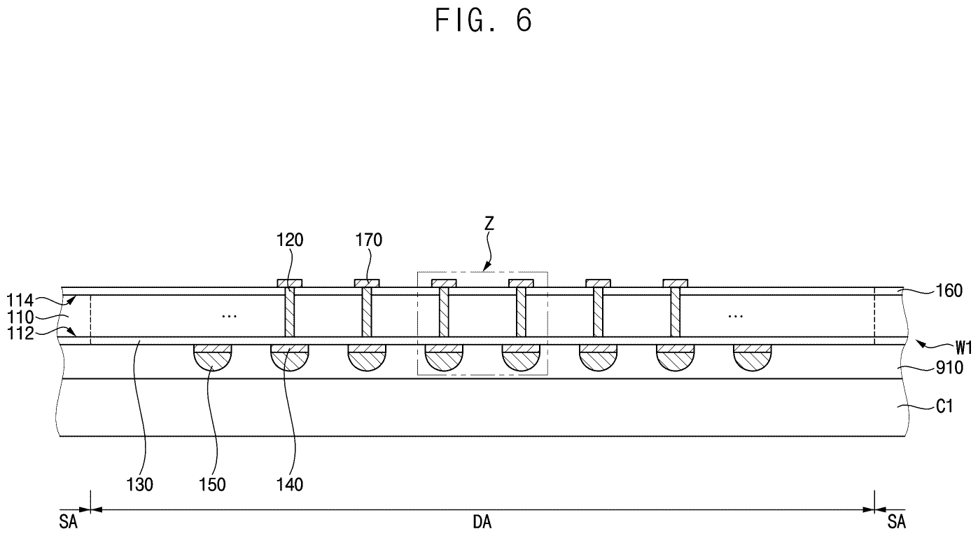

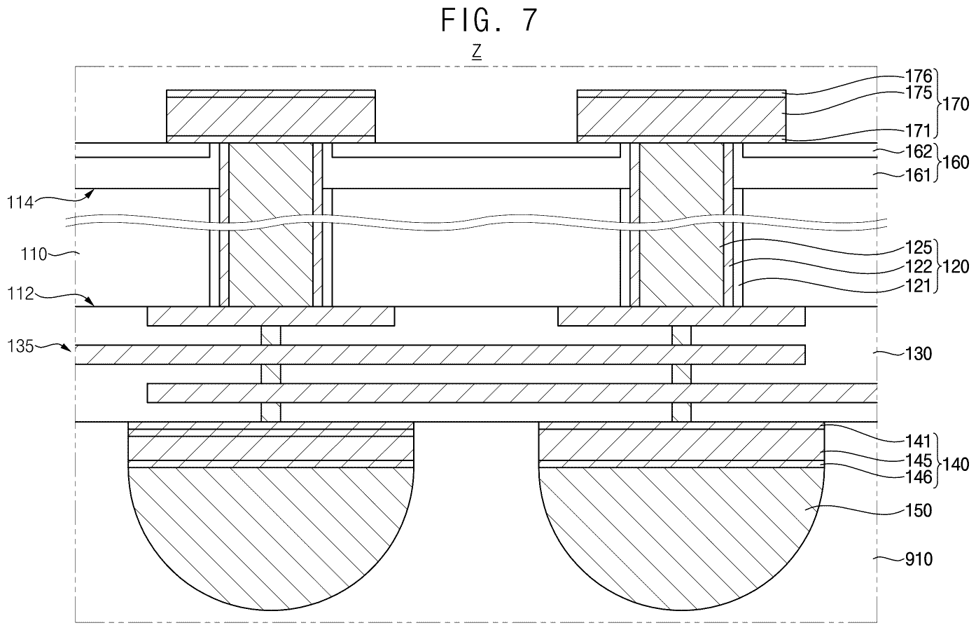

Referring to FIGS. 6 and 7, a first temporary bonding layer 910 may be attached to a first carrier substrate C1, and the first temporary bonding layer 910 may be bonded with an upper surface of the second insulating interlayer 130 including the first wiring structure 135 to cover the first conductive connection member 150 and the first conductive pad 140 on the first wafer W1. As a result, the first carrier substrate C1 may be bonded with the first wafer W1.

The first temporary bonding layer 910 may include a material losing adhesion by irradiation of light, e.g., UV light, IR light, or heat. In an example embodiment, the first temporary bonding layer 910 may include glue.

After flipping the first wafer W1, a portion of the first substrate 110 adjacent to the second surface 114 of the first substrate 110 may be removed by, e.g., a grinding process to expose an upper portion of the first through electrode structure 120.

In an example embodiment, an upper portion of the first insulation pattern 121 of the first through electrode structure 120 may also be removed by the grinding process, and thus an upper outer sidewall of the first barrier pattern 122 may be exposed.

A first protective layer structure may be formed on the second surface 114 of the first substrate 110 to cover the first through electrode structure 120. A planarization process may be performed on the first protective layer structure until an upper surface of the first through electrode 125 of the first through electrode structure 120 is exposed to form a first protective pattern structure 160.

In example embodiments, the planarization process may include a chemical mechanical polishing (CMP) process and/or an etch back process.

In example embodiments, the first protective layer structure may include first to third protective layers sequentially stacked in the vertical direction, and during the planarization process, the third protective layer may be removed and the second protective layer may partially remain. Thus, the first protective pattern structure 160 may include first and second protective patterns 161 and 162 sequentially stacked in the vertical direction. An upper outer sidewall of a portion of the first protective pattern 161 adjacent to the first through electrode structure 120 may be covered by the second protective pattern 162.

A second conductive pad 170 may be formed on the first protective pattern structure 160 and the first through electrode structure 120. In example embodiments, a plurality of second conductive pads 170 may be spaced apart from each other in the horizontal direction, and each of the second conductive pads 170 may contact an upper surface of the first through electrode structure 120 to be electrically connected thereto.

In an example embodiment, the second conductive pad 170 may be formed by the following processes.

Particularly, a second seed layer may be sequentially formed on the first protective pattern structure 160 and the first through electrode structure 120. A third photoresist pattern including a third opening partially exposing an upper surface of the second seed layer may be formed on the second seed layer. Finally, an electroplating process or an electroless plating process may be performed to form third and fourth conductive patterns 175 and 176 in the third opening.

The third photoresist pattern may be removed by, e.g., an ashing process and/or a stripping process to expose a portion of the second seed layer. The exposed portion of the second seed layer may be removed to form a second seed pattern 171 under the third conductive pattern 175.

Thus, a second conductive pad 170 may be formed, which may include the second seed pattern 171 and the third and fourth conductive patterns 175 and 176 sequentially stacked in the vertical direction.

Referring to FIG. 8, a first filling layer structure 180 and a first mask layer 810 may be sequentially formed on the first protective pattern structure 160 and the second conductive pad 170.

In example embodiments, the first filling layer structure 180 may include an inorganic material. In an example embodiment, the first filling layer structure 180 may include first and second filling layers 181 and 182 sequentially stacked, and the first filling layer 181 may include an oxide, e.g., silicon oxide, and the second filling layer 182 may include an insulating nitride, e.g., silicon nitride. In example embodiments, each of the first and second filling layers 181 and 182 may be conformally formed, and a thickness of the second filling layer 182 may be greater than a thickness of the first filling layer 181. For example, the first filling layer (e.g., first filler) 181 and/or second filling layer (e.g., second filler) 182 may have a constant thickness along a horizontal portion thereof.

The first mask layer 810 may include a material having a high etching selectivity with respect to the first filling layer structure 180, e.g., a conductive material such as a metal, a metal nitride, etc.

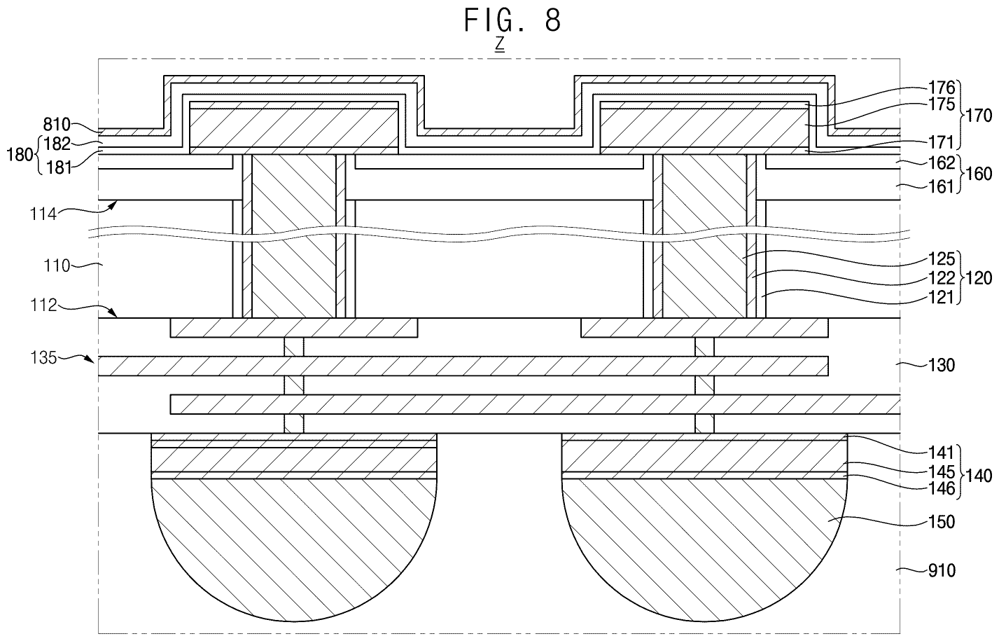

Referring to FIG. 9, a planarization process may be performed on the first mask layer 810 until a portion of the first filling layer structure 180 on an upper surface of the second conductive pad 170 is exposed. Thus, the first mask layer 810 may remain as a first mask 815 on a portion of the first filling layer structure 180 on a sidewall of the second conductive pad 170 and an upper surface of the first protective pattern structure 160.

The planarization process may include, e.g., a CMP process and/or an etch back process.

An etching process may be performed using the first mask 815 as an etching mask to partially etch the first filling layer structure 180, and thus the portion of the first filling layer structure 180 on the upper surface of the second conductive pad 170 may be removed so that a first filling pattern structure 185 may be formed on the sidewall of the second conductive pad 170 and the upper surface of the first protective pattern structure 160. During the etching process, an upper portion of the first mask 815 may also be removed.

The first filling pattern structure 185 may include a first filling pattern 186 and a second filling pattern 187 sequentially stacked.

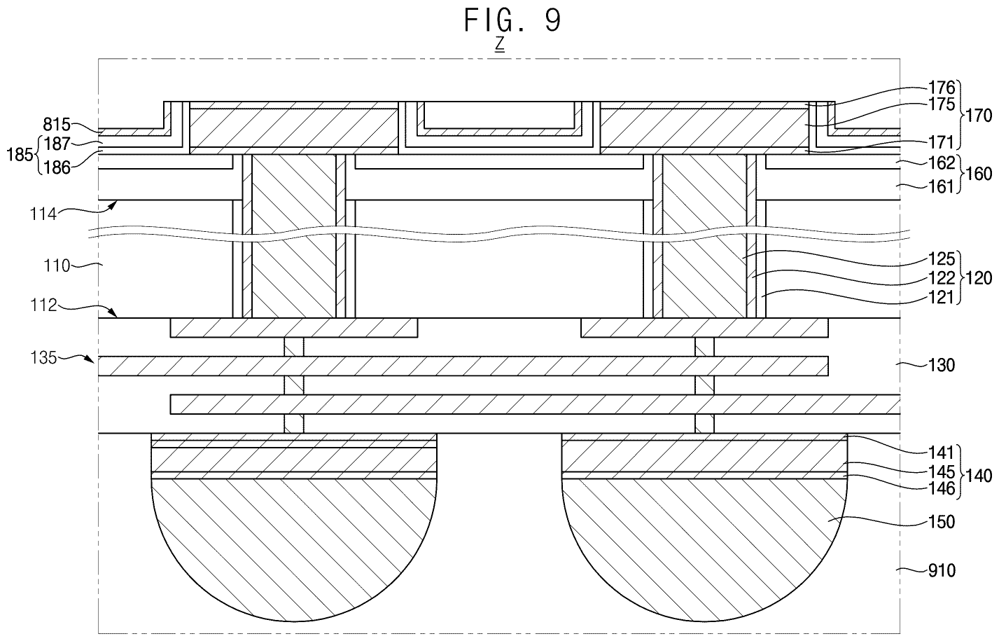

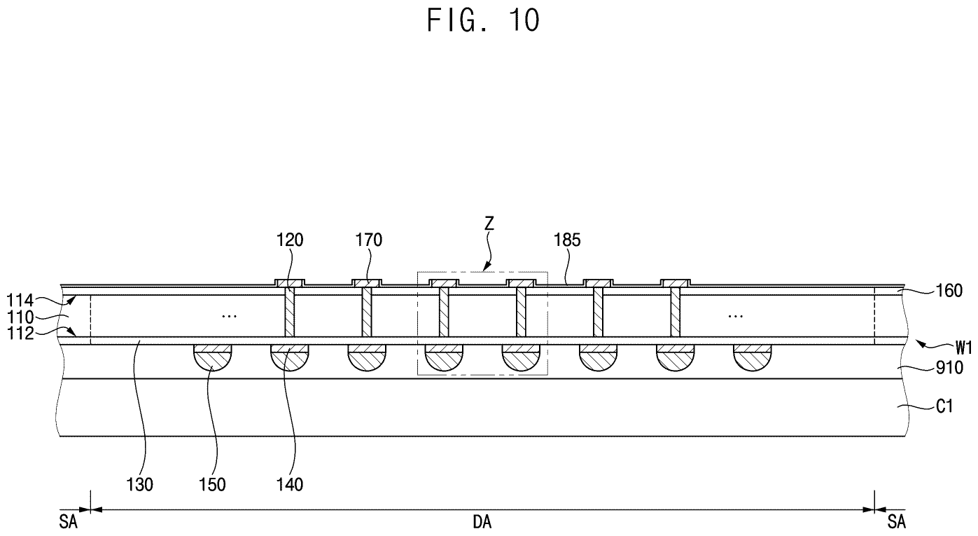

Referring to FIGS. 10 and 11, the remaining first mask 815 (shown in FIG. 9) may be removed, and an upper surface of the first filling pattern structure 185 may be exposed.

In example embodiments, the first mask 815 may be removed by, e.g., a wet etching process.

As the first mask 815 is removed, only the first filling pattern structure 185 may remain on the upper surface of the first protective pattern structure 160 and the sidewall of the second conductive pad 170.

Referring to FIGS. 12 and 13, a second wafer W2 may be provided.

In example embodiments, the second wafer W2 may include a second substrate 210 having first and second surfaces 212 and 214 opposite to each other in the vertical direction. Additionally, the second wafer W2 may include a plurality of die regions DA and a scribe lane region SA surrounding each of the die regions DA. The second wafer W2 may be cut along the scribe lane region SA by a sawing process, so as to singulate the second wafer W2 into a plurality of second semiconductor chips.

In the die region DA, a circuit device may be formed on the first surface 212 of the second substrate 210. The circuit device may include a memory device. The circuit device may include circuit patterns, and a third insulating interlayer may be formed on the first surface 212 of the second substrate 210 to cover the circuit patterns.

A fourth insulating interlayer 230 may be formed on the third insulating interlayer, and may contain a second wiring structure 235 therein. The second wiring structure 235 may include, e.g., wirings, vias, contact plugs, etc.

A third conductive pad 240 may be formed on fourth insulating interlayer 230 to contact the second wiring structure 235, so as to be electrically connected thereto. In example embodiments, a plurality of third conductive pads 240 may be spaced apart from each other in the horizontal direction.

In an example embodiment, the third conductive pad 240 may be formed by processes substantially the same as or similar to those of the first conductive pad 140. Thus, the third conductive pad 240 may be formed, which may include a third seed pattern 241 and the fifth and sixth conductive patterns 245 and 246 sequentially stacked in the vertical direction.

A second conductive connection member 250 may be formed on the third conductive pad 240. In an example embodiment, the second conductive connection member 250 may be formed by processes substantially the same as or similar to those of the first conductive connection member 150. Thus, the second conductive connection member 250 may have, e.g., a hemispherical shape or a semioval shape.

In example embodiments, a second through electrode structure 220 extending in the vertical direction through an upper portion of the second substrate 210 may be formed. For example, a portion of the second substrate 210 adjacent to the first surface 212 thereof may be formed. In example embodiments, a plurality of second through electrode structures 220 may be spaced apart from each other in the horizontal direction.

In an example embodiment, the second through electrode structure 220 may include a second through electrode 225 extending in the vertical direction, a second barrier pattern 222 covering a sidewall and a lower surface of the second through electrode 225, and a second insulation pattern 221 covering a sidewall and a lower surface of the second barrier pattern 222.

Referring to FIGS. 14 and 15, processes substantially the same as or similar to those illustrated with respect to FIGS. 6 to 11 may be performed.

Thus, a second temporary bonding layer 920 may be attached to a second carrier substrate C2, and the second temporary bonding layer 920 may be bonded with an upper surface of the fourth insulating interlayer 230 including the second wiring structure 235 to cover the second conductive connection member 250 and the third conductive pad 240 on the second wafer W2 so that the second carrier substrate C2 may be bonded with the second wafer W2. The second temporary bonding layer 920 may include a material losing adhesion by irradiation of light, e.g., UV light, IR light, or heat. In an example embodiment, the second temporary bonding layer 920 may include glue.

After flipping the second wafer W2, a portion of the second substrate 210 adjacent to the second surface 214 of the second substrate 210 may be removed by, e.g., a grinding process to expose an upper portion of the second through electrode structure 220. A second protective layer structure may be formed on the second surface 214 of the second substrate 210 to cover the second through electrode structure 220. Finally, a planarization process may be performed on the second protective layer structure until an upper surface of the second through electrode 225 of the second through electrode structure 220 is exposed to form a second protective pattern structure 260. The second protective layer structure 260 may include third and fourth protective patterns 261 and 262 sequentially stacked in the vertical direction.

A fourth conductive pad 270 may be formed on the second protective pattern structure 260 and the second through electrode structure 220. The fourth conductive pad 270 may include a fourth seed pattern 271 and seventh and eighth conductive patterns 275 and 276 sequentially stacked in the vertical direction.

A second filling layer structure and a second mask layer may be sequentially formed on the second protective pattern structure 260 and the second conductive pad 270. A planarization process may be performed on the second mask layer until a portion of the second filling layer structure on an upper surface of the fourth conductive pad 270 is exposed to form a second mask. An etching process may be performed using the second mask as an etching mask to partially etch the second filling layer structure. Thus, the portion of the second filling layer structure on the upper surface of the fourth conductive pad 270 may be removed so that a second filling pattern structure 285 may be formed on the sidewall of the fourth conductive pad 270 and the upper surface of the second protective pattern structure 260. The second filling pattern structure 285 may include a third filling pattern 286 and a fourth filling pattern 287 sequentially stacked.

The second mask may be removed by, e.g., a wet etching process.

Referring to FIGS. 16 and 17, after flipping the second wafer W2, the second wafer W2 may be attached to an upper surface of a release tape on a frame having a shape of, e.g., a ring.

The release tape may contact upper surfaces of the fourth conductive pad 270 and the second filling pattern structure 285 on the second surface 214 of the second wafer W2.

The second temporary bonding layer 920 attached to the second carrier substrate C2 may be separated from the second conductive connection member 250, the third conductive pad 240 and the fourth insulating interlayer 230 so that the second carrier substrate C2 may be separated from the second wafer W2.

After cutting the wafer W2 along the scribe lane region SA by a sawing process into second semiconductor chips 200, a bonding layer 700 may be formed on the fourth insulating interlayer 230 of each of the second semiconductor chips 200.

The bonding layer 700 may be formed on the fourth insulating interlayer 230 to cover the third conductive pad 240 and the second conductive connection member 250. The bonding layer 700 may include an NCF, e.g., thermosetting resin.

In some embodiments, the bonding layer 700 may be formed on the fourth insulating interlayer 230 of the second wafer W2, before the sawing process.

Each of the second semiconductor chips 200 may be mounted on the first wafer W1 such that the bonding layer 700 on each of the semiconductor chips 200 may contact upper surfaces of the second conductive pad 170 and the first filling pattern structure 185 of the first wafer W1. The second semiconductor chips 200 may be disposed on the respective die regions DA of the first wafer W1, and the second conductive connection member 250 of the second semiconductor chip 200 may contact the upper surface of the second conductive pad 170 of the first semiconductor chip.

A thermal compression process may be performed at a temperature equal to or less than about 400° C. so that the second semiconductor chips 200 may be bonded to the first wafer W1.

During the thermal compression process, the NCF included in the bonding layer 700 may be melted to have fluidity. Accordingly, the NCF may flow into a space between the second semiconductor chips 200 and the first wafer W1, for example, a space between the first filling pattern structure 185 of the first wafer W1 and the fourth insulating interlayer 230 of each of the second semiconductor chips 200 to cover a sidewall of a structure including the second conductive pad 170, the second conductive connection member 250 and the third conductive pad 240. The NCF may be cured.

In example embodiments, the first filling pattern structure 185 may be formed on the upper surface of the first protective pattern structure 160 and the second conductive pad 170 of the first wafer W1, and thus the space between the second conductive pads 170 spaced apart from each other in the horizontal direction may be partially filled with the first filling pattern structure 185.

In an example where the first filling pattern structure 185 is not formed, if an amount of the bonding layer 700 is also insufficient, the space between each of the second semiconductor chips 200 and the first wafer W1 may not be entirely filled with the bonding layer 700, generating a void. For example, in such a situation, the space between a plurality of the second conductive pads 170 in the horizontal direction may not be entirely filled with the bonding layer 700, therefore generating such a void. Furthermore, a portion of the second conductive connection member 250 having fluidity by the thermal compression process may move into the void. Consequently, the second conductive connection members 250 contacting upper surfaces of the second conductive pads 170, respectively, may be connected to each other, leading to an electrical short.

However, in example embodiments of the disclosed semiconductor package and methods of manufacturing thereof, the space between the second conductive pads 170 spaced apart from each other in the horizontal direction may be partially filled with the first filling pattern structure 185, so that the generation of the void during the thermal compression process may be reduced or prevented, and the electrical short between the second conductive connection members 250 may also be reduced or prevented. Accordingly, the disclosed semiconductor package and methods of manufacturing thereof can improve over other HBM packages by preventing electrical shorts.

Referring to FIGS. 18 and 19, third to fifth semiconductor chips 300, 400 and 500 may be sequentially stacked on the second semiconductor chip 200.

Processes substantially the same as or similar to those illustrated with respect to FIGS. 12 to 15 may be performed to form a plurality of third semiconductor chips 300, and processes substantially the same as or similar to those illustrated with respect to FIGS. 16 and 17 may be performed so that the third semiconductor chip 300 may be stacked on the second semiconductor chip 200.

In example embodiments, the third semiconductor chip 300 may include a third substrate 310 having first and second surfaces 312 and 314 opposite to each other in the vertical direction, and may be stacked on the second semiconductor chip 200 such that the bonding layer 700 covering a sixth insulating interlayer 330 on the first surface 312 of the third substrate 310 may contact the second filling pattern structure 285 on the second surface 214 of the second substrate 210. The third conductive connection member 350 of the third semiconductor chip 300 may be bonded with the fourth conductive pad 270 of the second semiconductor chip 300.

Likewise, the fourth semiconductor chip 400 including a fourth substrate 410 having first and second surfaces 412 and 414 opposite to each other in the vertical direction may be stacked on the third semiconductor chip 300, and the fourth conductive connection member 450 of the fourth semiconductor chip 400 may be bonded with the sixth conductive pad 370 of the third semiconductor chip 300. Additionally, the fifth semiconductor chip 500 including a fifth substrate 510 having first and second surfaces 512 and 514 opposite to each other in the vertical direction may be stacked on the fourth semiconductor chip 400, and the fifth conductive connection member 550 of the fifth semiconductor chip 500 may be bonded with the eighth conductive pad 470 of the fourth semiconductor chip 400.

Referring to FIGS. 1 to 3 again, a molding member 600 may be formed on the first wafer W1 to fill a space between structures each of which may include the second to fifth semiconductor chips 200, 300, 400 and 500.

In example embodiments, the molding member 600 may expose an upper surface of the fifth semiconductor chip 500.

The first wafer W1 may be cut along the scribe lane region SA by, e.g., a sawing process to be singulated into a plurality of first semiconductor chips 100.

During the sawing process, the molding member 600 may also be cut to cover sidewalls of the second to fifth semiconductor chips 200, 300, 400 and 500 on each of the first semiconductor chips 100.

The first temporary bonding layer 910 and the first carrier substrate C1 may be separated from each of the first semiconductor chips 100 to complete the manufacturing of the semiconductor package.

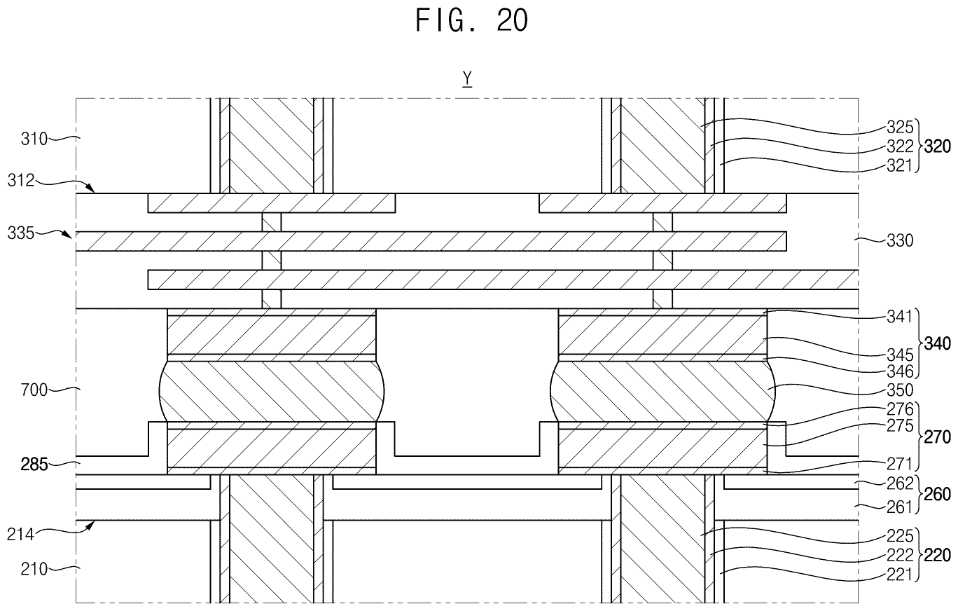

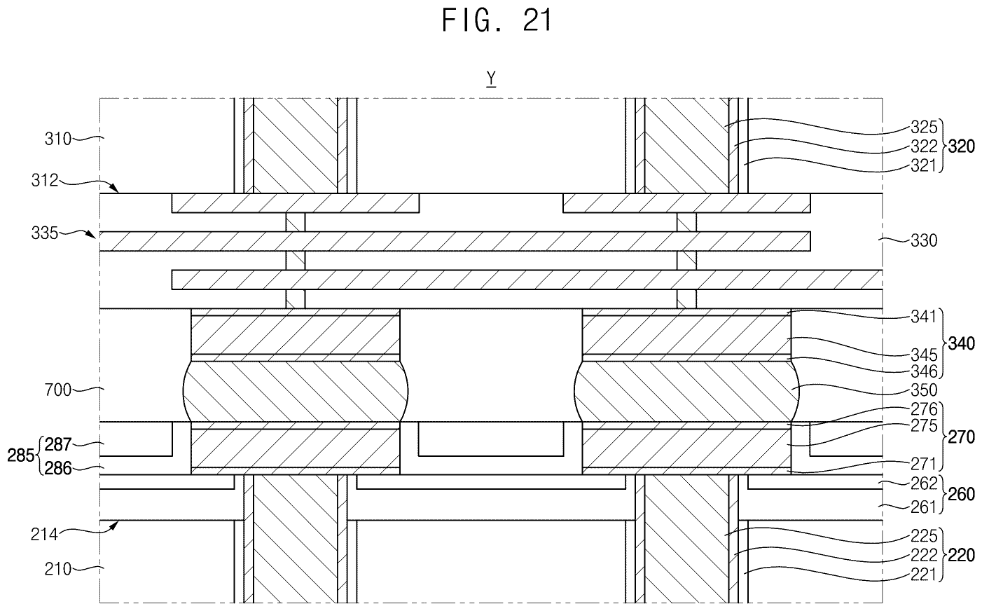

FIGS. 20 and 21 are cross-sectional views illustrating semiconductor packages in accordance with example embodiments, which may correspond to FIG. 3. These semiconductor packages may be substantially the same as or similar to that of FIGS. 1 to 3, except for the filling pattern structure, and thus repeated explanations are omitted herein.

Referring to FIG. 20, the second filling pattern structure 285 may include a single pattern instead of the third filling pattern 286 and the fourth filling pattern 287 sequentially stacked.

In example embodiments, the second filling pattern structure 285 may include an insulating nitride, e.g., silicon nitride having a thermal conductivity greater than that of silicon oxide. Thus, the second filling pattern structure 285 may have a thermal conductivity greater than that of an organic material such as NCF, and thus the disclosed semiconductor package including the second filling pattern structure 285 may have enhanced heat dissipation characteristics, for example compared with other HBM packages.

FIG. 20 shows that the second filling pattern structure 285 has the single pattern, however, the inventive concept may not be limited thereto, and any one of the first, third and fourth filling pattern structures 185, 385 and 485 may also include the single pattern.

Referring to FIG. 21, the second filling pattern structure 285 on the second protective pattern structure 260 may fill an entire space between the fourth conductive pads 270 spaced apart from each other in the horizontal direction, and thus an upper surface of the second filling pattern structure 285 may be substantially coplanar with an upper surface of the fourth conductive pad 270.

Thus, during the thermal compression process, the generation of the void due to the insufficient filling into the space between the fourth conductive pads 270 by the bonding layer 700 may be efficiently reduced or prevented.

FIG. 21 shows that the upper surface of the second filling pattern structure 285 is substantially coplanar with the upper surface of the fourth conductive pad 270, however, the inventive concept may not be limited thereto, and the first, third and fourth filling pattern structures 185, 385 and 485 may also be substantially coplanar with upper surfaces of the second, sixth and eighth conductive pads 170, 370 and 470, respectively.

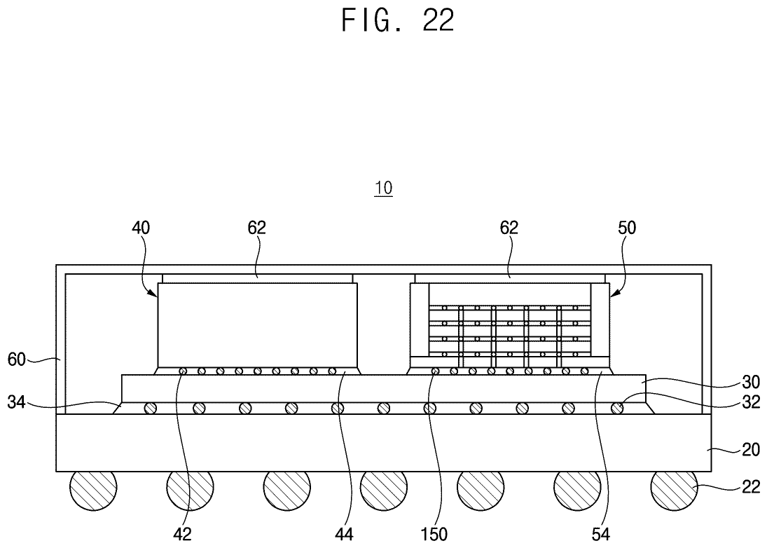

FIG. 22 is a cross-sectional view illustrating an electronic device in accordance with example embodiments.

This electronic device may include the semiconductor package shown in FIGS. 1 to 3 as a second semiconductor device 50, however, the inventive concept may not be limited thereto, and for example, the electronic device may include one of the semiconductor packages shown in FIGS. 20 and 21, respectively, as the second semiconductor device 50.

Referring to FIG. 22, an electronic device 10 may include a package substrate 20, an interposer 30, a first semiconductor device 40 and the second semiconductor device 50. The electronic device 10 may further include first, second and third underfill members 34, 44 and 54, a heat slug 60 and a heat dissipation member 62.

In example embodiments, the electronic device 10 may be a memory module having a 2.5D package structure, and thus may include the interposer 30 for electrically connecting the first and second semiconductor devices 40 and 50 to each other.

In example embodiments, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may be the semiconductor package of FIGS. 1 to 3.

In example embodiments, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be mounted on the package substrate 20 through a seventh conductive connection member 32. In example embodiments, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the seventh conductive connection member 32. The seventh conductive connection member 32 may include, e.g., a micro-bump. The silicon interposer may provide a high-density interconnection between the first and second semiconductor devices 40 and 50.

The first semiconductor device 40 may be disposed on the interposer 30. For example, the first semiconductor device 40 may be mounted on and bonded with the interposer 30 by a flip chip bonding process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through an eighth conductive connection member 42. For example, the eighth conductive connection member 42 may include, e.g., a micro-bump.

Alternatively, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded with the interposer 30 by, e.g., a flip chip bonding process. In this case, conductive pads of the second semiconductor device 50 may be electrically connected to conductive pads of the interposer 30 by the first conductive connection member 150.

Although a single first semiconductor device 40 and a single second semiconductor device 50 are disposed on the interposer 30, the inventive concept may not be limited thereto, and a plurality of first semiconductor devices 40 and/or a plurality of second conductive devices 50 may be disposed on the interposer 30.

In example embodiments, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members 34, 44 and 54 may include an adhesive containing an epoxy material.

The semiconductor device 50 may include a buffer die and a plurality of memory dies sequentially stacked on the buffer die. The buffer die and the memory dies may be electrically connected to each other by through electrodes, e.g., through-silicon vias (TSVs), and the through electrodes may be electrically connected to each other by conductive connection members. Data signals and control signals may be transferred to the buffer die and the memory dies by the through electrodes.

In example embodiments, the heat slug 60 may be formed on the package substrate 20 to thermally contact the first and second semiconductor devices 40 and 50. The heat dissipation member 62 may be disposed on an upper surface of each of the first and second semiconductor devices 40 and 50, and may include, e.g., thermal interface material (TIM). The heat slug 60 may thermally contact the first and second semiconductor devices 40 and 50 via the heat dissipation member 62.

A conductive pad may be formed at a lower portion of the package substrate 20, and a sixth conductive connection member 22 may be disposed beneath the conductive pad. In example embodiments, a plurality of sixth conductive connection members 22 may be spaced apart from each other in the horizontal direction. The sixth conductive connection member 22 may be, e.g., a solder ball. The electronic device 10 may be mounted on a module board via the sixth conductive connection members 22 to form a memory module.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of invention as defined in the claims.

What is claimed is:

1. A semiconductor package comprising:
a buffer die including:
a first substrate having first and second surfaces opposite to each other, respectively, in a vertical direction;
a through electrode extending through the first substrate and having a protrusion portion that protrudes beyond the second surface of the first substrate;
a protective pattern on the second surface of the first substrate, the protective pattern covering a sidewall of the protrusion portion of the through electrode;
a first conductive pad on the protective pattern, the first conductive pad contacting an upper surface of the through electrode; and
a filling pattern contacting an upper surface of the protective pattern and a sidewall of the first conductive pad and including an inorganic insulating material; and
a memory die on the buffer die, the memory die including:
a second substrate having first and second surfaces opposite to each other, respectively, in the vertical direction; and
a second conductive pad and a conductive connection terminal sequentially stacked in the vertical direction beneath the first surface of the second substrate,
wherein the first conductive pad of the buffer die contacts the conductive connection terminal of the memory die.

2. The semiconductor package according to claim 1, wherein a cross-sectional view in the vertical direction of a portion of the filling pattern adjacent to the first conductive pad has a shape of an “L.”

3. The semiconductor package according to claim 2, wherein an uppermost surface of the filling pattern is coplanar with an upper surface of the first conductive pad.

4. The semiconductor package according to claim 2, wherein the filling pattern includes:
a first filler including an oxide; and
a second filler on the first filler, the second filler including an insulating nitride.

5. The semiconductor package according to claim 4, wherein a thickness of the second filler is greater than a thickness of the first filler.

6. The semiconductor package according to claim 4, wherein an uppermost surface of the first filler is coplanar with an uppermost surface of the second filler.

7. The semiconductor package according to claim 2, wherein a horizontal portion of the filling pattern has a constant thickness.

8. The semiconductor package according to claim 2, wherein the filling pattern has a flat upper surface, and the flat upper surface of the filling pattern is coplanar with an upper surface of the first conductive pad.

9. The semiconductor package according to claim 1, wherein the filling pattern does not contact an upper surface of the first conductive pad. 10 A semiconductor package comprising:
a first memory die including:
a first substrate having first and second surfaces opposite to each other, respectively, in a vertical direction;
a first through electrode extending through the first substrate and having a first protrusion portion that protrudes beyond the second surface of the first substrate;
a first protective pattern on the second surface of the first substrate, the first protective pattern covering a sidewall of the first protrusion portion of the first through electrode;
a first conductive pad on the first protective pattern, the first conductive pad contacting an upper surface of the first through electrode; and
a first filling pattern contacting an upper surface of the first protective pattern and a sidewall of the first conductive pad and including an inorganic insulating material; and
a second memory die on the first memory die, the second memory die including:
a second substrate having first and second surfaces opposite to each other, respectively, in the vertical direction; and
a second conductive pad and a conductive connection terminal sequentially stacked in the vertical direction beneath the first surface of the second substrate,
wherein the first conductive pad of the first memory die contacts the conductive connection terminal of the second memory die.

11. The semiconductor package according to claim 10, wherein a cross-sectional view in the vertical direction of a portion of the first filling pattern adjacent to the first conductive pad has a shape of an “L.”

12. The semiconductor package according to claim 11, wherein an uppermost surface of the first filling pattern is coplanar with an upper surface of the first conductive pad.

13. The semiconductor package according to claim 10, wherein the first filling pattern includes:
a first filler including an oxide; and
a second filler on the first filler, the second filler including an insulating nitride.

14. The semiconductor package according to claim 13, wherein a thickness of the second filler is greater than a thickness of the first filler.

15. The semiconductor package according to claim 13, wherein an uppermost surface of the first filler is coplanar with an uppermost surface of the second filler.

16. The semiconductor package according to claim 11, wherein a horizontal portion of the first filling pattern has a constant thickness.

17. The semiconductor package according to claim 10, wherein the second memory die includes:
a second through electrode extending through the second substrate and having a second protrusion portion that protrudes beyond the second surface of the second substrate;
a second protective pattern on the second surface of the second substrate, the second protective pattern covering a sidewall of the second protrusion portion of the second through electrode;
a third conductive pad on the second protective pattern, the third conductive pad contacting an upper surface of the second through electrode; and
a second filling pattern contacting an upper surface of the second protective pattern and a sidewall of the third conductive pad and including an inorganic insulating material.

18. A method of manufacturing a semiconductor package, the method comprising:
forming first and second semiconductor chips, each of forming the first semiconductor chip and forming the second semiconductor chip including:
sequentially forming a first conductive pad and conductive connection terminal on a first surface of a substrate, the substrate having the first surface and a second surface opposite to each other, respectively, in a vertical direction and including a through electrode extending through the substrate;
removing a portion of the substrate adjacent to the second surface of the substrate to expose the through electrode;
forming a second conductive pad on the second surface of the substrate to contact an upper surface of the through electrode; and
forming a filling pattern on the second surface of the substrate to cover a sidewall of the second conductive pad;
forming a bonding layer on the first surface of the substrate included in the second semiconductor chip to cover the first conductive pad and the conductive connection terminal of the second semiconductor chip; and
thermally compressing the first and second semiconductor chips so that the conductive connection terminal of the second semiconductor chip contacts the second conductive pad of the first semiconductor chip.

19. The method according to claim 18, wherein forming the filling pattern on the second surface of the substrate to cover the sidewall of the second conductive pad includes:
forming a filling layer structure on the second surface of the substrate to cover the second conductive pad;
forming an etching mask layer on the filling layer structure;
performing a planarization process on the etching mask layer until an upper surface of a portion of the filling layer structure on an upper surface of the second conductive pad to form an etching mask; and
performing an etching process on the filling layer structure using the etching mask.

20. The method according to claim 18, wherein thermally compressing the first and second semiconductor chips includes generating no void at a portion of the bonding layer adjacent to the second conductive pad between the first and second semiconductor chips.
